(19) United States
(12) Patent Application Publication
(10) Pub. No.: US 2026/0136814 A1
(43) Pub. Date: May 14, 2026

(54) LIGHT-EMITTING DEVICE AND ELECTRONIC EQUIPMENT

(71) Applicant: Sony Semiconductor Solutions Corporation, Kanagawa (JP)

(72) Inventors: Toshiya Yonehara, Kanagawa (JP); Tokihiro Yokono, Kanagawa (JP); Shintaro Nakano, Kanagawa (JP); Takashi Sakairi, Kanagawa (JP); Tsuyoshi Okazaki, Kangawa (JP)

(21) Appl. No.: 18/880,658

(22) PCT Filed: Aug. 3, 2023
(86) PCT No.: PCT/JP2023/028356

§ 371 Date: Jan. 2, 2025

(30) Foreign Application Priority Data
Aug. 9, 2022 (JP) 2022-127379

(51) Int. Cl. H10K 59/80; H10K 50/856; H10K 50/858; H10K 59/38; H10K 59/50

(52) U.S. Cl. CPC H10K 59/879; H10K 50/856; H10K 50/858; H10K 59/38; H10K 59/50; H10K 59/87

(57) ABSTRACT

Light-emitting devices with improved frontal luminance are disclosed. In one example, a light-emitting device includes a plurality of light-emitting elements arranged two-dimensionally, a metamaterial, and an optical control layer provided between the plurality of light-emitting elements and the metamaterial. A ratio (L/D) of a distance L between the light-emitting elements and the metamaterial to a size D of a pixel is greater than or equal to 0.2 and less than or equal to 1.8.

### TECHNICAL FIELD

The present disclosure relates to a light-emitting device and electronic equipment including the light-emitting device.

### BACKGROUND ART

The application of metamaterials to light-emitting devices has been under consideration. For example, Patent Document 1 discloses a display device 100 capable of focusing blue light, green light, and red light respectively emitted from a first emitter structure 122, a second emitter structure 124, and a third emitter structure 126 on an image plane 132 with a nanostructure 130.

### CITATION LIST

### Patent Document

Patent Document 1: WO 2018/222688 A

### SUMMARY OF THE INVENTION

### Problems to be Solved by the Invention

In recent years, it has been desired to improve the frontal luminance of light-emitting devices. Patent Document 1, however, does not disclose a configuration to improve the frontal luminance of the light-emitting device (display device 100), and there is room for improvement.

It is therefore an object of the present disclosure to provide a light-emitting device with an improved frontal luminance and electronic equipment including the light-emitting device.

### Solutions to Problems

In order to solve the above-described problems, a light-emitting device according to the present disclosure includes:
a plurality of light-emitting elements arranged two-dimensionally;
a metamaterial; and
an optical control layer provided between the plurality of light-emitting elements and the metamaterial, in which
a ratio (L/D) of a distance L between the light-emitting elements and the metamaterial to a size D of a pixel is greater than or equal to 0.2 and less than or equal to 1.8.

Electronic equipment according to the present disclosure includes the light-emitting device.

In the present disclosure, in a case where a pixel includes a plurality of subpixels, the pixel may refer to a subpixel.

### BRIEF DESCRIPTION OF DRAWINGS

FIG. 1 is a plan view of a display device according to a first embodiment.

FIG. 2 is an enlarged plan view of a part of a display region.

FIG. 3 is an enlarged plan view of a part of the display region.

FIG. 4 is an enlarged plan view of a part of a display region.

FIG. 5 is a cross-sectional view taken along line A-A in FIG. 2.

FIG. 6A is a plan view of a metalens of a subpixel. FIG. 6B is a cross-sectional view taken along line A-A in FIG. 6A.

FIG. 7 is a plan view of a metalens of a subpixel.

FIGS. 8A, 8B, and 8C are cross-sectional views for describing the reason for specifying a numerical range of a ratio (L/D) of a distance L between a light-emitting element and a metamaterial to a size D of the subpixel.

FIGS. 9A and 9B are cross-sectional views for describing a relationship between refractive indices of a protective layer and an optical control layer, and frontal luminance.

FIG. 10A is a diagram illustrating a geometric shape of a lens. FIG. 10B is a diagram illustrating phase information of the lens illustrated in FIG. 10A. FIG. 10C is a diagram illustrating a metalens that functions in a manner similar to the lens illustrated in FIG. 10A.

FIG. 11A is a plan view of a metasurface including cylindrical nanostructures. FIG. 11B is a perspective view of the metasurface including cylindrical nanostructures.

FIG. 12A is a plan view of a metasurface including quadrangular prismatic nanostructures. FIG. 12B is a perspective view of the metasurface including quadrangular prismatic nanostructures.

FIG. 13 is a diagram illustrating phase changes of the cylindrical metasurface illustrated in FIGS. 11A and 11B and the quadrangular prismatic metasurface illustrated in FIGS. 12A and 12B.

FIGS. 14A, 14B and 14C are diagrams for describing a method for manufacturing the display device according to the first embodiment.

FIGS. 15A and 15B are diagrams for describing the method for manufacturing the display device according to the first embodiment.

FIG. 16A is a cross-sectional view for describing the function of an existing lens. FIG. 16B is a cross-sectional view for describing the function of the metalens.

FIG. 17 is a cross-sectional view of a display device according to a modification.

FIG. 18 is an enlarged plan view of a part of a display region of a display device according to a second embodiment.

FIG. 19A is a plan view of a metalens of a subpixel. FIG. 19B is a cross-sectional view taken along line A-A in FIG. 19A.

FIG. 20A is a perspective view of a lens array with a gap provided between lenses. FIG. 20B is a perspective view of a lens array with no gap provided between lenses.

FIG. 21 is a cross-sectional view of a display device according to a third embodiment.

FIG. 22 is an exploded cross-sectional view for describing a configuration of a metalens.

FIG. 23 is a plan view for describing the configuration of the metalens.

FIG. 24 is a cross-sectional view for describing the configuration of the metalens.

FIGS. 25A and 25B are diagrams for describing a relationship between sizes of a lens and a light source.

FIG. 26A is a cross-sectional view of a display device in which adjacent lenses do not overlap. FIG. 26B is a cross-sectional view of a display device in which adjacent lenses overlap.

FIG. 27 is a plan view for describing a configuration of a metalens.

FIG. 28 is a plan view for describing a configuration of a metalens.

FIG. 29 is a cross-sectional view for describing a configuration of a metalens.

FIG. 30 is a cross-sectional view for describing a configuration of a metalens.

FIG. 31 is a cross-sectional view for describing the configuration of the metalens.

FIG. 32 is a cross-sectional view of a display device according to a fourth embodiment.

FIG. 33A is a plan view of a compound lens of a subpixel. FIG. 33B is a cross-sectional view taken along line A-A in FIG. 33A.

FIG. 34 is a cross-sectional view of a display device according to Modification 1.

FIG. 35A is a plan view of a compound lens of a subpixel. FIG. 35B is a cross-sectional view taken along line A-A in FIG. 35A.

FIG. 36 is a cross-sectional view of a display device according to Modification 2.

FIG. 37A is a plan view of a compound lens of a subpixel. FIG. 37B is a cross-sectional view taken along line A-A in FIG. 37A.

FIG. 38 is a cross-sectional view of a display device according to Modification 3.

FIG. 39A is a plan view of a compound lens of a subpixel. FIG. 39B is a cross-sectional view taken along line A-A in FIG. 39A.

FIG. 40 is a cross-sectional view of a display device according to a fifth embodiment.

FIG. 41 is a graph showing a difference in phase modulation amount with or without a phase shifter.

FIG. 42 is a cross-sectional view of a display device according to a modification.

FIG. 43 is a cross-sectional view of a display device according to a modification.

FIG. 44 is a plan view of a metasurface of a display device according to a sixth embodiment.

FIG. 45A is a plan view of a metalens corresponding to a symmetric lens (non-decentered lens). FIG. 45B is a plan view of a metalens corresponding to an asymmetric lens (decentered lens).

FIG. 46A is a schematic cross-sectional view for describing a first example of a resonator structure. FIG. 46B is a schematic cross-sectional view for describing a second example of the resonator structure.

FIG. 47A is a schematic cross-sectional view for describing a third example of the resonator structure. FIG. 47B is a schematic cross-sectional view for describing a fourth example of the resonator structure.

FIG. 48A is a schematic cross-sectional view for describing a fifth example of the resonator structure. FIG. 48B is a schematic cross-sectional view for describing a sixth example of the resonator structure.

FIG. 49 is a schematic cross-sectional view for describing a seventh example of the resonator structure.

FIG. 50A is a front view illustrating an example of an external appearance of a digital still camera. FIG. 50B is a rear view illustrating an example of an external appearance of the digital still camera.

FIG. 51 is a perspective view of an example of an external appearance of a head-mounted display.

FIG. 52 is a perspective view illustrating an example of an external appearance of a television device.

FIG. 53 is a perspective view illustrating an example of an external appearance of a see-through head-mounted display.

FIG. 54 is a perspective view illustrating an example of an external appearance of a smartphone.

FIG. 55A is a diagram illustrating an example of an interior state of a vehicle as viewed from the rear to the front of the vehicle. FIG. 55B is a diagram illustrating an example of an internal state of the vehicle as viewed from the oblique rear to the oblique front of the vehicle.

### MODE FOR CARRYING OUT THE INVENTION

Embodiments of the present disclosure will be described in the following order with reference to the drawings. Note that the same or corresponding portions will be denoted by the same reference signs in all the drawings of the following embodiments.
1 First embodiment (Example of display device)
2 Second embodiment (Example of display device)
3 Third embodiment (Example of display device)
4 Fourth embodiment (Example of display device)
5 Fifth embodiment (Example of display device)
6 Sixth embodiment (Example of display device)
7 Modifications
8 Example of resonator structure applied to each embodiment
9. Application examples

### 1 First Embodiment

### Configuration of Display Device 101

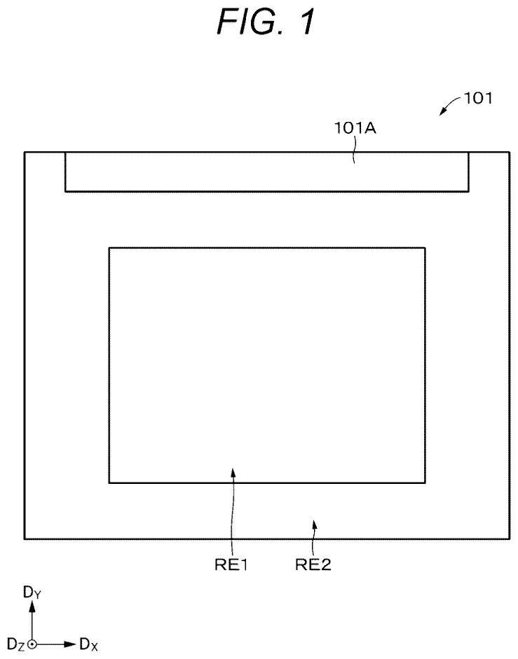

FIG. 1 is a plan view illustrating an example of a configuration of a display device 101 according to a first embodiment. The display device 101 includes a display region RE1 and a peripheral region RE2 provided around the display region RE1.

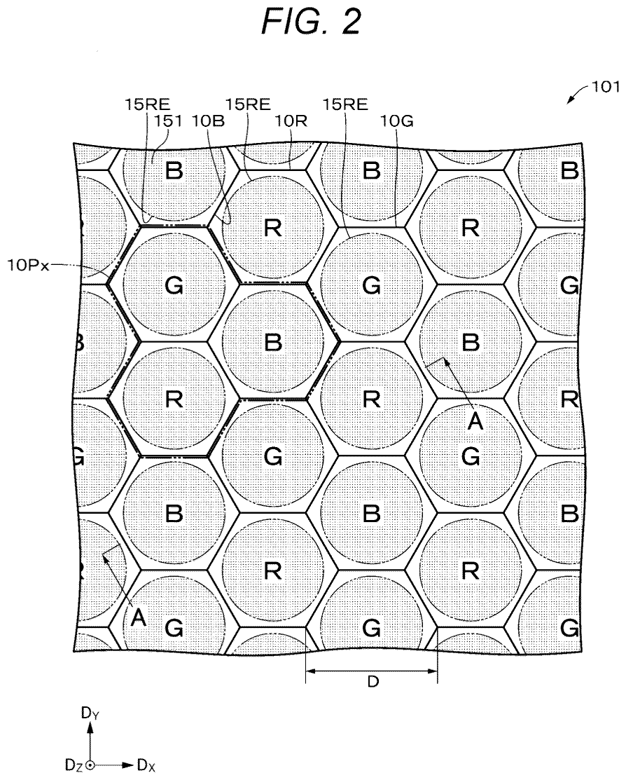

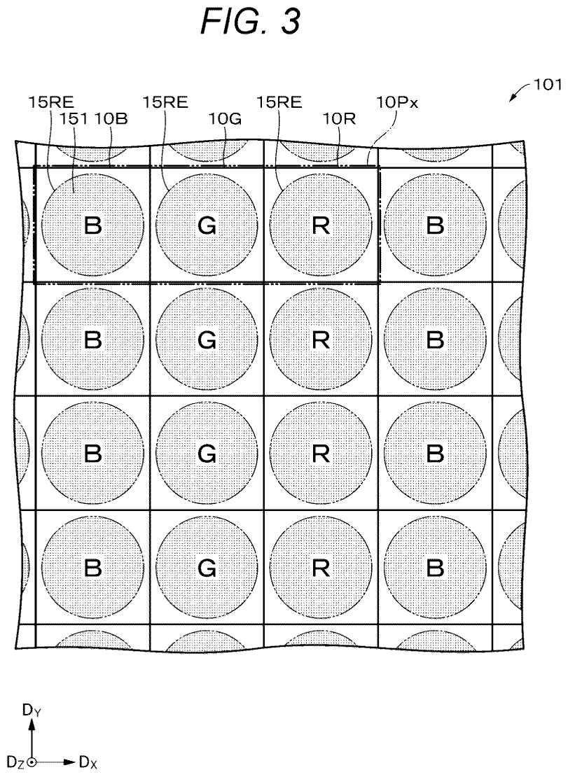

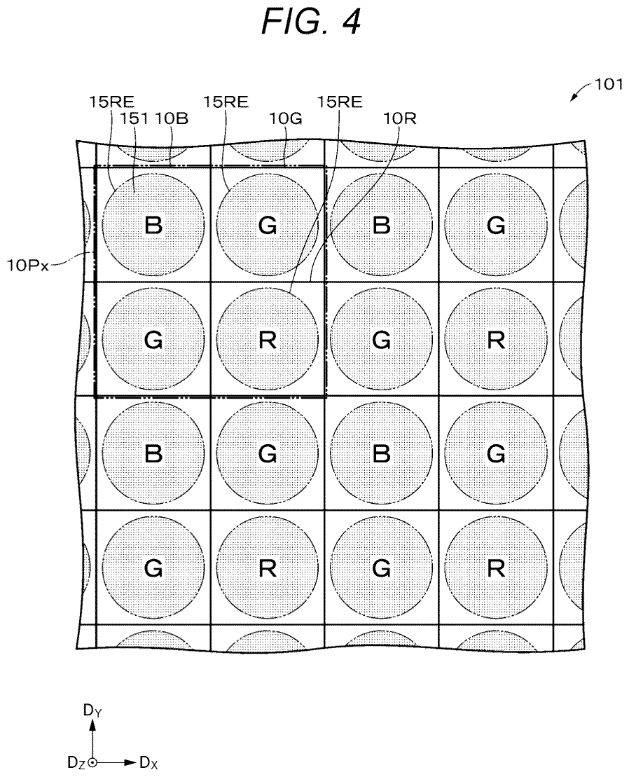

FIG. 2 is an enlarged plan view of a part of the display region RE1 of the display device 101. A plurality of subpixels 10R, 10G, and 10B is two-dimensionally arranged in a prescribed arrangement pattern in the display region RE1. FIG. 2 illustrates an example where the prescribed arrangement pattern is a delta array. The prescribed arrangement pattern is not limited to the delta array, and may be a stripe array as illustrated in FIG. 3, may be a square array as illustrated in FIG. 4, or may be an array other than these. A pad 101A, a video display driver (not illustrated), and the like are provided in the peripheral region RE2. A flexible printed circuit (FPC) (not illustrated) may be connected to the pad 101A.

The subpixel 10R can emit red light (first light). The subpixel 10G can emit green light (second light). The subpixel 10B can emit blue light (third light). Red is an example of a first primary color among the three primary colors. Green is an example of a second primary color among the three primary colors. Blue is an example of a third primary color among the three primary colors. In FIG. 2, sections denoted by symbols “R”, “G”, and “B” represent the subpixel 10R, the subpixel 10G, and the subpixel 10B, respectively.

In the following description, the subpixels 10R, 10G, and 10B may be referred to as subpixel 10 unless otherwise distinguished. Each pixel (one pixel) 10Px includes a plurality of adjacent subpixels 10R, 10G, and 10B.

The shape of the subpixels 10R, 10G, and 10B is not limited to a specific shape, and examples of the shape include a polygonal shape, a circular shape, an elliptical shape, and the like in plan view. Examples of the polygonal shape include, but are not limited to, a quadrilateral shape such as a rectangular shape and a hexagonal shape. Herein, it is assumed that the rectangular shape includes a square shape as well. Note that FIG. 2 illustrates an example where the subpixels 10R, 10G, and 10B each have a hexagonal shape in plan view, and FIGS. 3 and 4 illustrate an example where the subpixels 10R, 10G, and 10B each have a quadrilateral shape in plan view. The upper limit of the size of the subpixels 10R, 10G, and 10B is preferably less than or equal to 10 μm, more preferably less than or equal to 8 μm, still more preferably less than or equal to 5 μm, less than or equal to 4 μm, or less than or equal to 3.5 μm. The lower limit of the size of the subpixels 10R, 10G, and 10B is, for example, greater than or equal to 1 μm.

The display device 101 is an example of a light-emitting device. The display device 101 may be a top-emitting OLED display device. The display device 101 may be a microdisplay. The display device 101 may be provided in a virtual reality (VR) device, a mixed reality (MR) device, an augmented reality (AR) device, an electronic view finder (EVF), a small projector, or the like.

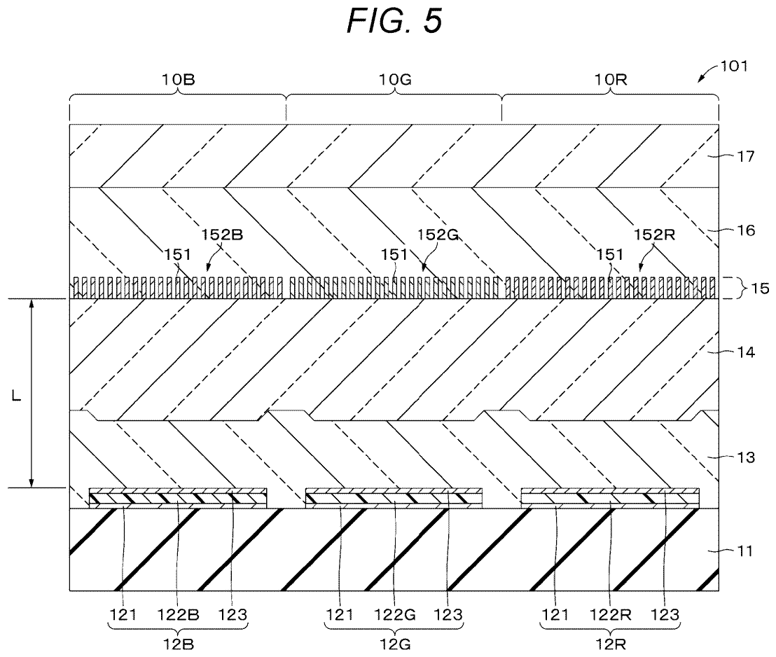

FIG. 5 is a cross-sectional view taken along line A-A in FIG. 2. The display device 101 includes a drive substrate 11, a plurality of light-emitting elements (first light-emitting elements) 12R, a plurality of light-emitting elements (second light-emitting elements) 12G, a plurality of light-emitting elements (third light-emitting elements) 12B, a protective layer (first protective layer) 13, an optical control layer 14, a metamaterial 15, a protective layer (second protective layer) 16, and a cover layer 17.

In the following description, a surface on the top side (display surface side) of the display device 101 may be referred to as first surface, and a surface on a bottom side (opposite side to the display surface) of the display device 101 may be referred to as second surface, for each layer constituting the display device 101. Note that, in the following description, the light-emitting elements 12R, 12G, and 12B may be collectively referred to as light-emitting element 12 unless otherwise distinguished.

Herein, the plan view refers to a plan view when an object is viewed from a direction D_{Z} (hereinafter, referred to as “frontal direction D_{Z}”) perpendicular to the first surface. Herein, the horizontal direction relative to the display region RE1 is referred to as horizontal direction D_{X}, and the vertical direction relative to the display region RE1 is referred to as vertical direction D_{Y}.

### Drive Substrate 11

The drive substrate 11 is a so-called backplane and drives the plurality of light-emitting elements 12R, 12G, and 12B. The drive substrate 11 includes, for example, a substrate and an insulating layer in this order.

A plurality of drive circuits, a plurality of wiring lines (none of which are illustrated), and the like are provided on the first surface of the substrate. The substrate may include, for example, a semiconductor that is easy to form, such as a transistor, or may include glass or resin with low permeability to moisture and oxygen. Specifically, the substrate may be a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from a group consisting of polymethyl methacrylate, polyvinyl alcohol, polyvinyl phenol, polyethersulfone, polyimide, polycarbonate, polyethylene terephthalate, polyethylene naphthalate, and the like.

The insulating layer is provided on the first surface of the substrate to cover the plurality of drive circuits, the plurality of wiring line, and the like for planarization. The insulating layer may insulate the plurality of drive circuits, the plurality of wiring line, and the like provided on the first surface of the substrate from the plurality of light-emitting elements 12R, 12G, and 12B.

The insulating layer may be an organic insulating layer, an inorganic insulating layer, or a laminate thereof. The organic insulating layer includes at least one selected from the group consisting of a polyimide resin, an acrylic resin, a novolac resin, and the like, for example. The inorganic insulating layer includes at least one selected from the group consisting of a silicon oxide (SiOₓ), a silicon nitride (SiNₓ), a silicon oxynitride (SiOₓN_{y}), and the like, for example.

### Light-Emitting Elements 12R, 12G, and 12B

The emission colors of the light-emitting element 12R, the light-emitting element 12G, and the light-emitting element 12B are different. The light-emitting element 12R can emit red light under the control of the drive circuit and the like. The light-emitting element 12G can emit green light under the control of the drive circuit and the like. The light-emitting element 12B can emit blue light under the control of the drive circuit and the like. The light-emitting element 12 is an organic light emitting diode (OLED) element. The light-emitting element 12R belongs to the subpixel 10R. The light-emitting element 12G belongs to the subpixel 10G. The light-emitting element 12B belongs to the subpixel 10B.

The plurality of light-emitting elements 12R, the plurality of light-emitting elements 12G, and the plurality of light-emitting elements 12B are arranged two-dimensionally on the first surface of the drive substrate 11 in a prescribed arrangement pattern. The prescribed arrangement pattern is as described for the prescribed arrangement pattern of the plurality of subpixels 10.

The light-emitting element 12R includes a first electrode 121, an OLED layer 122R, and a second electrode 123 in this order on the first surface of the drive substrate 11. The light-emitting element 12G includes a first electrode 121, an OLED layer 122G, and a second electrode 123 in this order on the first surface of the drive substrate 11. The light-emitting element 12B includes a first electrode 121, an OLED layer 122B, and a second electrode 123 in this order on the first surface of the drive substrate 11.

### OLED Layers 122R, 122G, 122B

The OLED layer 122R can emit red light. The OLED layer 122G can emit green light. The OLED layer 122B can emit blue light.

The OLED layers 122R, 122G, and 122B are each provided between the first electrode 121 and the second electrode 123. The OLED layer 122R includes an organic light-emitting layer that can emit red light (hereinafter, referred to as “red organic light-emitting layer”). The OLED layer 122R includes an organic light-emitting layer that can emit green light (hereinafter, referred to as “green organic light-emitting layer”). The OLED layer 122B includes an organic light-emitting layer that can emit blue light (hereinafter, referred to as “blue organic light-emitting layer”). In the following description, the OLED layers 122R, 122G, and 112B may be collectively referred to as OLED layer 122 unless otherwise distinguished. Furthermore, the red organic light-emitting layer, the green organic light-emitting layer, and the blue light-emitting layer may be collectively referred to as organic light-emitting layer unless otherwise distinguished.

The OLED layers 122R, 122G, and 112B may each include a laminate including the corresponding organic light-emitting layer, and in this case, a part of the laminate (for example, an electron injection layer) may be an inorganic layer. The OLED layer 122R includes, for example, a hole injection layer, a hole transport layer, the red organic light-emitting layer, an electron transport layer, and an electron injection layer in this order from the first electrode 121 to the second electrode 123. The OLED layer 122G includes, for example, a hole injection layer, a hole transport layer, the green organic light-emitting layer, an electron transport layer, and an electron injection layer in this order from the first electrode 121 to the second electrode 123. The OLED layer 122G includes, for example, a hole injection layer, a hole transport layer, the blue organic light-emitting layer, an electron transport layer, and an electron injection layer in this order from the first electrode 121 to the second electrode 123.

The red organic light-emitting layer can emit red light through recombination of holes injected from the first electrode 121 and electrons injected from the second electrode 123. The green organic light-emitting layer can emit green light through a phenomenon similar to the red organic light-emitting layer. The blue organic light-emitting layer can emit blue light through a phenomenon similar to the red organic light-emitting layer.

The hole injection layer can enhance the efficiency of hole injection into each organic light-emitting layer and suppress leakage. The hole transport layer can enhance the efficiency of hole transport to the each organic light-emitting layer. The electron injection layer can enhance the efficiency of electron injection into each organic light-emitting layer. The electron transport layer can enhance the efficiency of electron transport to each organic light-emitting layer.

### First Electrode 121

The first electrode 121 is provided on the second surface of the OLED layer 122. The first electrode 121 is provided individually for the plurality of light-emitting elements 12 in the display region RE1. That is, the first electrode 121 is divided between the light-emitting elements 12 adjacent to each other in the in-plane direction in the display region RE1. The first electrode 121 is an anode. When a voltage is applied between the first electrode 121 and the second electrode 123, holes are injected from the first electrode 121 into the OLED layer 122.

The first electrode 121 may include, for example, a metal layer, or may include a metal layer and a transparent conductive oxide layer. In a case where the first electrode 121 includes a metal layer and a transparent conductive oxide layer, the transparent conductive oxide layer is preferably provided adjacent to the OLED layer 122 from the viewpoint of placing a layer with a high work function adjacent to the OLED layer 122.

The metal layer also functions as a reflective layer that reflects light generated in the OLED layer 122. The metal layer includes, for example, at least one metal element selected from a group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd and AlCu.

An underlayer (not illustrated) may be provided adjacent to the second surface of the metal layer. The underlayer is provided to improve the crystallographic orientation of the metal layer during formation of the metal layer. The underlayer includes, for example, at least one metal element selected from a group consisting of titanium (Ti) and tantalum (Ta). The underlayer may include the at least one metal element described above as a constituent element of an alloy.

The transparent conductive oxide layer includes a transparent conductive oxide. The transparent conductive oxide includes, for example, at least one selected from the group consisting of an indium-containing transparent conductive oxide (hereinafter referred to as “indium-based transparent conductive oxide”), a tin-containing transparent conductive oxide (hereinafter referred to as “tin-based transparent conductive oxide”), and a zinc-containing transparent conductive oxides (hereinafter referred to as “zinc-based transparent conductive oxide”).

The indium-based transparent conductive oxide includes, for example, an indium tin oxide (ITO), an indium zinc oxide (IZO), an indium gallium oxide (IGO), an indium gallium zinc oxide (IGZO), or a fluorine-doped indium oxide (IFO). Among these transparent conductive oxides, the indium tin oxide (ITO) is particularly preferable. This is because the indium tin oxide (ITO) has a particularly low barrier for hole injection into the OLED layers 122R, 122G, and 122B in terms of work function, and accordingly, the drive voltage for the display device 101 can be particularly reduced. The tin-based transparent conductive oxide includes, for example, a tin oxide, an antimony-doped tin oxide (ATO), or a fluorine-doped tin oxide (FTO). The zinc-based transparent conductive oxide includes, for example, a zinc oxide, an aluminum-doped zinc oxide (AZO), a boron-doped zinc oxide, or a gallium-doped zinc oxide (GZO).

### Second Electrode 123

The second electrode 123 is provided on the first surface of the OLED layer 122. The second electrode 123 is a cathode. When a voltage is applied between the first electrode 121 and the second electrode 123, electrons are injected from the second electrode 123 into the OLED layer 122. The second electrode 123 is transparent to each light emitted from the OLED layers 122R, 122G, and 122B. The second electrode 123 is preferably a transparent electrode transparent to visible light. Herein, visible light refers to light in a wavelength range of 360 nm to 830 nm.

The second electrode 123 preferably includes a material having as high transparent as possible and a low work function in order to enhance luminous efficiency. The second electrode 123 includes, for example, at least one of a metal layer or a transparent conductive oxide layer. More specifically, the second electrode 123 includes a single-layer film of a metal layer or a transparent conductive oxide layer, or a multilayer film of a metal layer and a transparent conductive oxide layer. In a case where the second electrode 123 includes a multilayer film, the metal layer may be provided adjacent to the OLED layer 122, or the transparent conductive oxide layer may be provided adjacent to the OLED layer 122, but, from the viewpoint of placing a layer with a low work function adjacent to the OLED layer 122, the metal layer is preferably provided adjacent to the OLED layer 122.

The metal layer includes, for example, at least one metal element selected from a group consisting of magnesium (Mg), aluminum (Al), silver (Ag), calcium (Ca), and sodium (Na). The metal layer may include the at least one metal element described above as a constituent element of an alloy. Specific examples of the alloy includes an MgAg alloy, an MgAl alloy, an AlLi alloy, and the like. The transparent conductive oxide layer includes a transparent conductive oxide. As the transparent conductive oxide, a material similar to the transparent conductive oxide of the first electrode 121 described above can be exemplified.

### Protective Layer 13

The protective layer 13 is transparent to each light emitted from the light-emitting elements 12R, 12G, and 12B. The second electrode 123 is preferably transparent to visible light. The protective layer 13 can protect the plurality of light-emitting elements 12 and the like. The protective layer 13 is provided on the first surface of the drive substrate 11 to cover the plurality of light-emitting elements 12. The protective layer 13 shields the light-emitting element 12 from the outside air, and prevents moisture infiltration into the light-emitting element 12 from the external environment. Furthermore, in a case where the second electrode layer 123 includes a metal layer, the protective layer 13 may have a function of preventing oxidation of the metal layer.

The protective layer 13 includes, for example, an inorganic material or a polymer resin, each having low hygroscopicity. The protective layer 13 may have a single layer structure or a multilayer structure. In a case where the thickness of the protective layer 13 is increased, a multilayer structure is preferable. This is to alleviate the internal stress in the protective layer 13. The inorganic material includes, for example, at least one selected from a group consisting of a silicon oxide (SiOₓ), a silicon nitride (SiNₓ), a silicon oxynitride (SiOₓN_{y}), a titanium oxide (TiOₓ), an aluminum oxide (AlOₓ), and the like. The polymer resin includes, for example, at least one selected from a group consisting of a thermosetting resin, an ultraviolet curable resin, and the like. Specifically, the polymer resin includes, for example, at least one selected from the group consisting of an acrylic resin, a polyimide resin, a novolac resin, an epoxy resin, a norbornene resin, a parylene resin, and the like.

### Optical Control Layer 14

The optical control layer 14 is transparent to each light emitted from the light-emitting elements 12R, 12G, and 12B. The optical control layer 14 is preferably transparent to visible light. The optical control layer 14 is provided between the protective layer 13 and the metamaterial 15. The optical control layer 14 can control a distance (optical path length) between the plurality of light-emitting elements 12 and the metamaterial 15. It is preferable that the surface of the optical control layer 14 be free from irregularities and to be nearly flat.

The optical control layer 14 includes, for example, an inorganic material or a polymer resin. The optical control layer 14 preferably includes a high dielectric material having a high refractive index. The high dielectric material may be an inorganic material or a polymer resin. The inorganic material can be, for example, silicon nitride (SiNₓ). The inorganic material having a higher refractive index can include, for example, at least one selected from the group consisting of a metal oxide, a metal nitride, and the like. The metal oxide includes, for example, at least one selected from the group consisting of a titanium oxide (TiOₓ), a tantalum oxide (TaOₓ), a zinc oxide (ZnOₓ), and the like. The metal nitride includes, for example, a gallium nitride (GaNₓ).

For example, in a case where a size D of the light-emitting element 12 is less than or equal to 10 μm, a thickness T of the optical control layer 14 is preferably greater than or equal to 0.1 μm and less than 1.8×D μm.

### Metamaterial 15

The metamaterial 15 is a metasurface that is a two-dimensional metamaterial and includes a plurality of nanostructures (meta-atoms) 151 with a size less than or equal to the wavelength of light. Here, the light may be light emitted from the light-emitting element 12. In a case where the light emitted from the light-emitting element 12 has a broad emission spectrum, the wavelength of light can be defined as, for example, the wavelength corresponding to the peak intensity of the emission spectrum. Alternatively, the wavelength of light can be defined as the smaller of either the maximum wavelength on the long wavelength side where the intensity becomes, for example, 1/20 of the peak intensity, or the maximum wavelength of visible light. In the first embodiment, an example where the metamaterial 15 is a two-dimensional metamaterial will be described, but the metamaterial 15 may include a three-dimensional metamaterial, or may include both the two-dimensional metamaterial and the three-dimensional metamaterial.

The plurality of nanostructures 151 is arranged two-dimensionally on the first surface of the optical control layer 14. The plurality of nanostructures (meta-atoms) 151 may be uniformly arranged at equal intervals. Each nanostructure 151 is, for example, a dielectric pillar. The shape of the dielectric pillar is not limited to a specific shape, but examples of the shape include a cylindrical shape, an elliptical cylindrical shape, a polygonal prismatic shape such as a quadrangular prismatic shape, and the like. The plurality of nanostructures 151 may include dielectric pillars of two or more shapes.

The plurality of nanostructures 151 includes a plurality of metalens (first metalens) 152R, a plurality of metalens (second metalens) 152G, and a plurality of metalens (third metalens) 152B. In the following description, the metalens 152R, 152G, and 152B may be collectively referred to as metalens 152 unless otherwise distinguished.

The metalens 152R can focus the light emitted from light-emitting element 12R and incident from below. The metalens 152G can focus the light emitted from light-emitting element 12G and incident from below. The metalens 152B can focus the light emitted from light-emitting element 12B and incident from below. Each of the metalenses 152R, 152G, and 152B may collimate the light incident from below and emit the light as parallel light (parallel light approximately perpendicular to the display surface).

The metalenses 152R, 152G, and 152B may have a function corresponding to a lens having a geometric convex or concave surface. The configurations of the metalens 152R, 152G, and 152B may be different from each other or may be the same, but the configurations preferably vary in a manner that depends on the light incident from the light-emitting elements 12R, 12B, and 12G. For example, at least one of the arrangement, height, shape, or the like of the nanostructures 151 constituting the metalenses 152R, 152G, and 152B may be different among the metalens 152R, 152G, and 152B.

The metalens 152R is provided above the light-emitting element 12R. The metalens 152R includes a plurality of nanostructures 151 provided above the light-emitting element 12R. The metalens 152G is provided above the light-emitting element 12G. The metalens 152G includes a plurality of nanostructures 151 provided above the light-emitting element 12G. The metalens 152B is provided above the light-emitting element 12B. The metalens 152B includes a plurality of nanostructures 151 provided above the light-emitting element 12B.

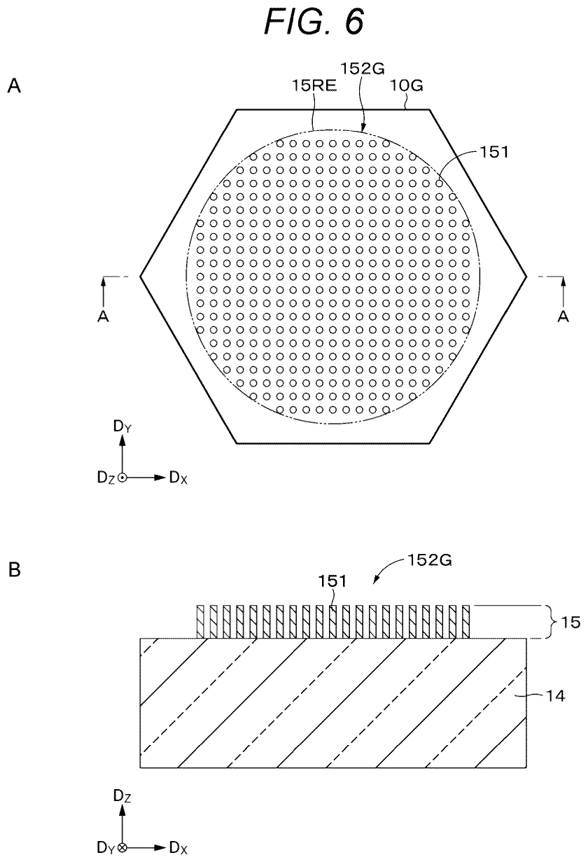

FIG. 6A is a plan view of the metalens 152G of the subpixel 10G. FIG. 6B is a cross-sectional view taken along line A-A in FIG. 6A. Note that the metalens 10R of the subpixel 152R and the metalens 10B of the subpixel 152B may have a configuration substantially similar to that of the metalens 10G of the subpixel 152G; therefore, the illustration of the metalens 152R and metalens 152B will be omitted. The plurality of nanostructures 151 may be provided in a part of the subpixel 10. For example, the plurality of nanostructures 151 may be provided only in a central portion, that is, the inner side of the peripheral edge portion of the subpixel 10 without being provided in the peripheral edge portion of the subpixel 10 in plan view. A region where the plurality of nanostructures 151 is provided is referred to as nanostructure formation region 15RE. The peripheral edge portion of the subpixel 10 refers to a region extending inward from the peripheral edge of the subpixel 10 by a predetermined width. It is preferable that the center position of the nanostructure formation region 15RE in plan view substantially coincide with the center position of the subpixel 10 in plan view.

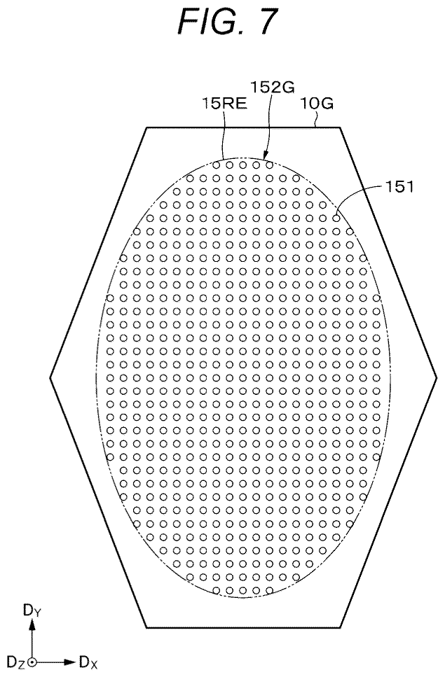

The shape of the nanostructure formation region 15RE in plan view can be selected on the basis of desired characteristics, and is not limited to a specific shape. For example, the shape of the nanostructure formation region 15RE in plan view may be a circular shape as illustrated in FIG. 6A, or may be a shape other than the circular shape as illustrated in FIG. 7. Examples of the shape other than the circular shape include an elliptical shape, a polygonal shape (such as a quadrilateral shape and a hexagonal shape), and the like.

As illustrated in FIG. 6A, regarding the shape of the nanostructure formation region 15RE in plan view, the nanostructure 151 may have the same size in the horizontal direction D_{X} and vertical direction D_{Y}, or as illustrated in FIG. 7, the nanostructure 151 may have different sizes in the horizontal direction D_{X} and vertical direction D_{Y}. In this case, viewing angle characteristics of the display device 101 can be adjusted individually in the horizontal direction D_{X} and the vertical direction D_{Y}.

### Protective Layer 16

The protective layer 16 is provided to fill at least the metamaterial 15, that is, a space between the plurality of nanostructures 151. The plurality of nanostructures 151 may be covered to protect the metamaterial 15. With this configuration, it is possible to prevent, for example, collapse or destruction of the nanostructure 151 caused by external factors. It is therefore possible to prevent degradation of the characteristics of metamaterial 15 caused by external factors. The protective layer 16 may function as an adhesive layer for bonding the drive substrate 11 having the plurality of light-emitting elements 12 and the like provided on the first surface and the cover layer 17.

The protective layer 16 is transparent to each light emitted from the light-emitting elements 12R, 12G, and 12B. The protective layer 16 is preferably transparent to visible light. The protective layer 16 includes, for example, at least one selected from a group consisting of a thermosetting resin, an ultraviolet curable resin, and the like. The protective layer 16 is different in refractive index from the nanostructure 151. The protective layer 16 may be higher in refractive index than the nanostructure 151, or the protective layer 16 may be lower in refractive index than the nanostructure 151.

A magnitude Δn (=|n₁₆−n₁₅₁|) of the difference between a refractive index n₁₆ of the protective layer 16 and a refractive index n₁₅₁ of the nanostructure 151 is preferably greater than or equal to 0.2, more preferably greater than or equal to 0.3, and still more preferably greater than or equal to 0.5, from the viewpoint of preventing an aspect ratio of the nanostructure 151 from becoming excessively large. Herein, the refractive index n₁₆ of the protective layer 16 and the refractive index n₁₅₁ of the nanostructure 151 each represent a refractive index for light with a wavelength of 589.3 nm (sodium D line).

Either the protective layer 16 or the nanostructure 151 with a higher refractive index includes, for example, a high dielectric material including an inorganic material or a polymer resin. The inorganic material being the high dielectric material includes, for example, at least one selected from the group consisting of a metal oxide, a metal nitride, and the like. The metal oxide includes, for example, at least one selected from the group consisting of a titanium oxide (TiOₓ), a tantalum oxide (TaOₓ), a zinc oxide (ZnOₓ), and the like. The metal nitride includes, for example, a gallium nitride (GaNₓ). Either the protective layer 16 or the nanostructure 151 with a lower refractive index includes, for example, a dielectric material including an inorganic material or a polymer resin. The inorganic material can be, for example, a silicon oxide (SiOₓ).

### Cover Layer 17

The cover layer 17 seals each part such as the light-emitting element 12 and the metamaterial 15 provided on the drive substrate 11. The cover layer 17 is transparent to each light emitted from the light-emitting elements 12R, 12G, and 12B. The cover layer 17 is preferably transparent to visible light. The cover layer 17 is provided on the first surface of the protective layer 16. The cover layer 17 is, for example, a glass substrate.

### Ratio (L/D) of Distance L Between Light-Emitting Element 12 and Metamaterial 15 to Size D of Subpixel 10

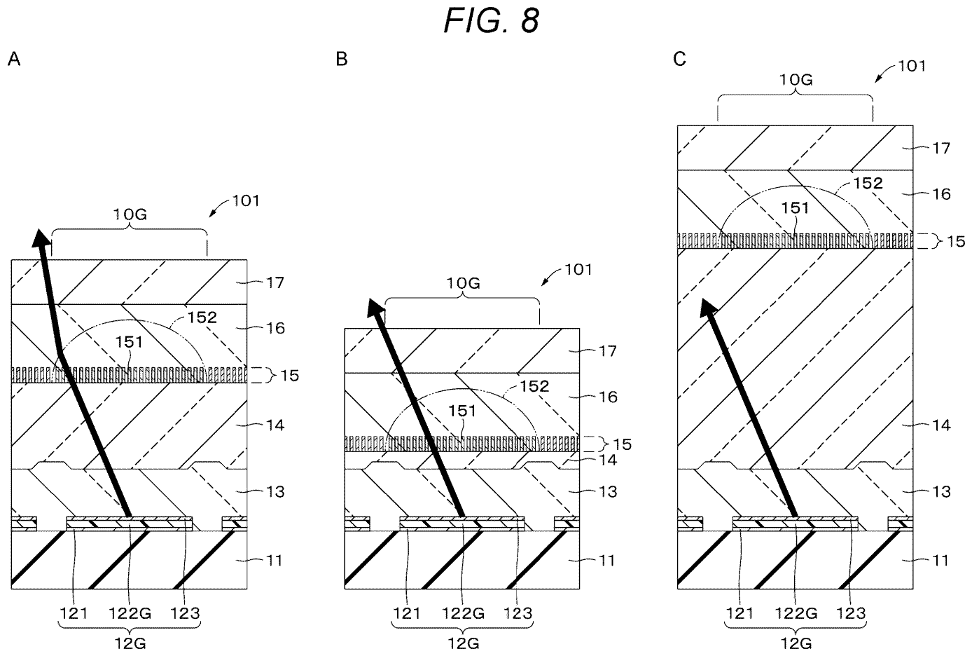

FIGS. 8A, 8B, and 8C are cross-sectional views for describing the reason for specifying a numerical range of the ratio (L/D) of the distance L between the light-emitting element 12 and the metamaterial 15 to the size D of the subpixel 10. Note that, in FIGS. 8A, 8B, and 8C, the metalens 152 is virtually represented by a geometric lens shape. The ratio (L/D) of the distance L between the light-emitting element 12 and the metamaterial 15 to the size D of the subpixel 10 is preferably greater than or equal to 0.2 or less than or equal to 1.8, more preferably greater than or equal to 0.35 and less than or equal to 1.5, and still more preferably greater than or equal to 0.65 and less than or equal to 1.2. When the ratio (L/D) is greater than or equal to 0.2 and less than or equal to 1.8, as illustrated in FIG. 8A, the light emitted from the light-emitting element 12 at a wide angle is bent and focused in the frontal direction by the metalens 152. Therefore, the effect of the metalens 152 in improving the frontal luminance is enhanced.

In a case where the ratio (L/D) is out of the range of greater than or equal to 0.2 and less than or equal to 1.8, there is a possibility that the effect of improving the frontal luminance decreases as follows. That is, when the ratio (L/D) is less than 0.2, as illustrated in FIG. 8B, the light emitted from the light-emitting element 12 at a wide angle is hardly bent by the metalens 152, the light focusing function of the metalens 152 deteriorates, and the light is emitted from the metalens 152 in substantially the same direction as the incident direction. Therefore, there is a possibility that the effect of the metalens 152 in improving the frontal luminance decreases. On the other hand, when the ratio (L/D) is greater than 1.8, as illustrated in FIG. 8C, the light emitted from the light-emitting element 12 at a wide angle is less likely to enter the metalens 152. Therefore, there is a possibility that the effect of the metalens 152 in improving the frontal luminance decreases.

For example, in a case where the size D of light-emitting element 12 is greater than or equal to 1 μm and less than or equal to 10 μm, the distance L between light-emitting element 12 and the metamaterial 15 is preferably greater than or equal to 0.2×D μm and less than or equal to 1.8×D μm, and more preferably greater than or equal to 0.35×D μm and less than or equal to 1.5×D μm. When the distance L between the light-emitting element 12 and the metamaterial 15 is greater than or equal to 0.2×D μm and less than or equal to 1.8×D μm, as illustrated in FIG. 8A, the light emitted from light-emitting element 12 at a wide angle is bent and focused in the frontal direction by the metalens 152. Therefore, the effect of the metalens 152 in improving the frontal luminance is enhanced.

Herein, the distance L between the light-emitting element 12 and the metamaterial 15 refers to a distance from the geometric center position of the first surface (upper surface) of the light-emitting element 12 to the metamaterial 15. In a case where the size D of the subpixel 10 varies in a manner that depends on the measurement direction, the size D of the subpixel 10 refers to the long side of a quadrilateral circumscribing the subpixel 10. For example, in a case where the subpixel 10 has a rectangular shape, the size D of the subpixel 10 is the long side of the subpixel 10. For example, in a case where the subpixel 10 has a hexagonal shape, the quadrilateral circumscribing the subpixel 10 refers to a quadrilateral that is in contact with opposite sides and in contact with two corners located between the opposite sides.

### Relationship Between Refractive Index and Film Thickness of Optical Control Layer 14 and Protective Layer 13

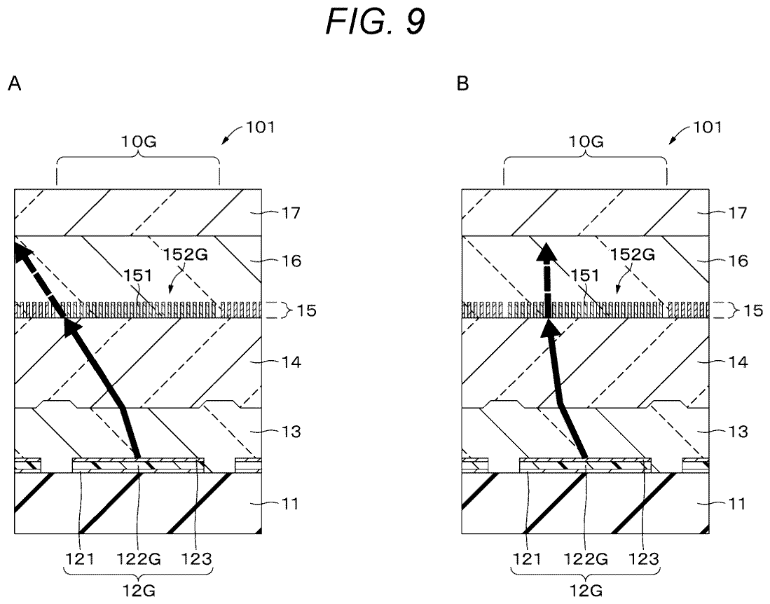

A refractive index n₁₄ of the optical control layer 14 is preferably high. Specifically, for example, the refractive index n₁₄ of the optical control layer 14 is preferably greater than or equal to 1.8 and less than or equal to 2.0. The refractive index of the optical control layer 14 is preferably higher than a refractive index n₁₃ of the protective layer 13 serving as an underlayer of the optical control layer 14. For example, in a case where the refractive index n₁₄ of the optical control layer 14 is higher than the refractive index n₁₃ of the protective layer 13, as illustrated in FIGS. 9A and 9B, the spread of light in the in-plane direction can be suppressed as compared with a case where the refractive index n₁₄ of the optical adjustment layer 14 is lower than the refractive index n₁₃ of the protective layer 13. Furthermore, the light whose spread is suppressed easily enters the vicinity of the center of the metalens 152. With the effective refractive index in the metalens 152 in this case taken into consideration, the central portion of the metalens 152 is higher in effective refractive index than the outer peripheral portion of the metalens 152; therefore, when the light enters the central portion of the metalens 152, the light tends to pass easily in the vertical direction. With the fact that the metalens 152 is designed on the basis of information regarding a phase that passes in the vertical direction (frontal direction D_{Z}) taken into consideration, the more easily light passes through the metalens 152 in the vertical direction, the easier it is to obtain designed characteristics, and the higher the luminous efficiency (frontal luminance) tends to be. Herein, the refractive index n₁₄ of the optical control layer 14 and the refractive index n₁₃ of the protective layer 13 refer to a refractive index for light with a wavelength of 589.3 nm (sodium D line).

From a more practical viewpoint, it is preferable that a layer with a higher refractive index, whether it is the optical control layer 14 with the refractive index n₁₄ or the protective layer 13 with the refractive index n₁₃ serving as an underlayer, have a greater thickness. The greater the thickness of the layer with a higher refractive index, the more the spread of light is suppressed, and the more easily the light enters the vicinity of the center of the metalens 152. The central portion of the metalens 152 is higher in effective refractive index than the outer peripheral portion of the metalens 152, so that when the light enters the central portion of the metalens 152, the light tends to pass more easily in the vertical direction. With the fact that the metalens 152 is designed on the basis of information regarding the phase that passes in the vertical direction (frontal direction D_{Z}) taken into consideration, the more easily light passes through the metalens 152 in the vertical direction, the easier it is to obtain designed characteristics, and the higher the luminous efficiency (frontal luminance) tends to be.

### Formation of Metalens 152 With Any Desired Shape by Nanostructure 151

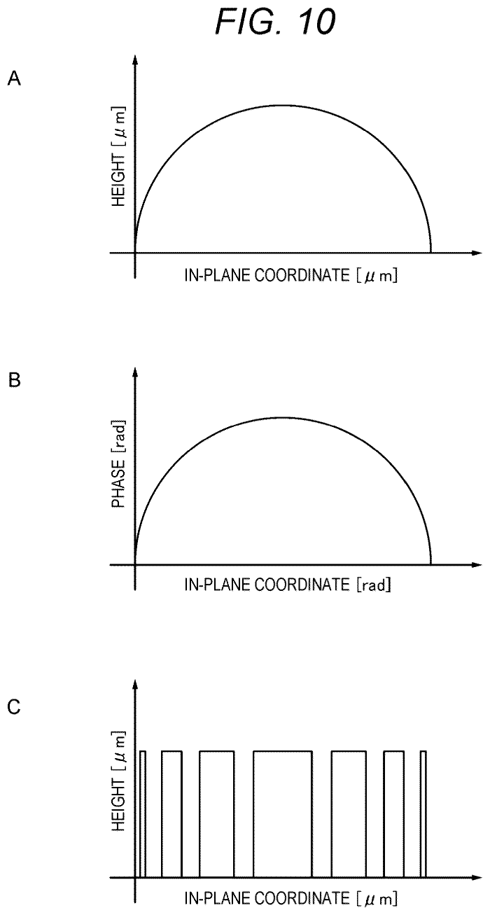

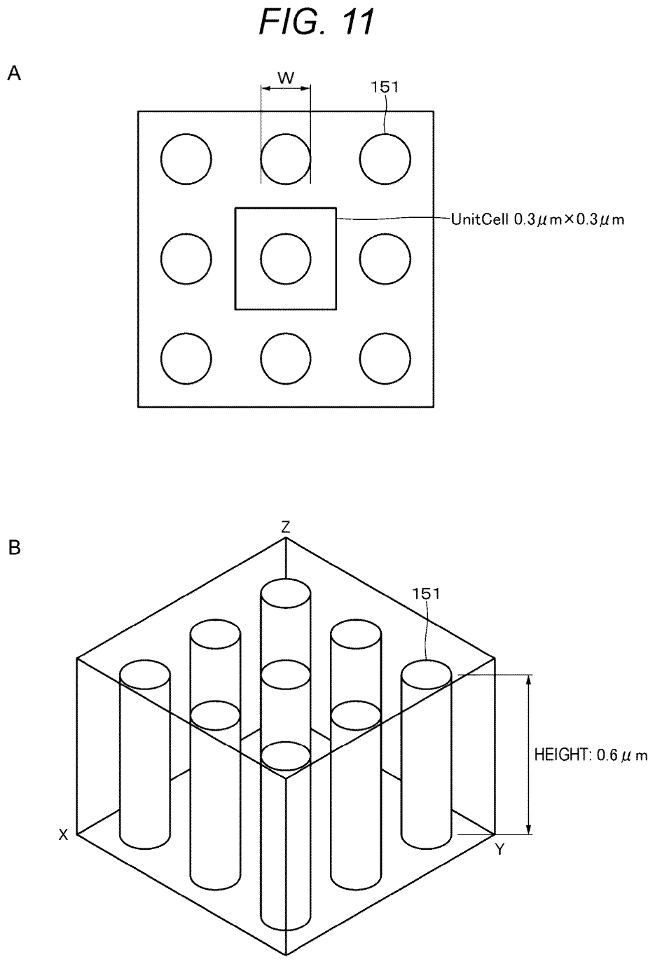

As illustrated in FIGS. 10A, 10B, and 10C, the metalens 152 is designed to reproduce information regarding the phase that passes through a curved lens in the vertical direction using meta-atoms such as the nanostructures 151. Therefore, a lens with any desired shape can be formed only by changing the in-plane dimension or arrangement of the meta-atoms such as the nanostructures 151. Furthermore, as illustrated in FIGS. 10A, 10B, and 10C, not only the lens shape in cross-sectional view but also the lens shape in plan view can be formed as desired, as illustrated in FIGS. 6A and 7.

### Advantages of Smaller Subpixel 10

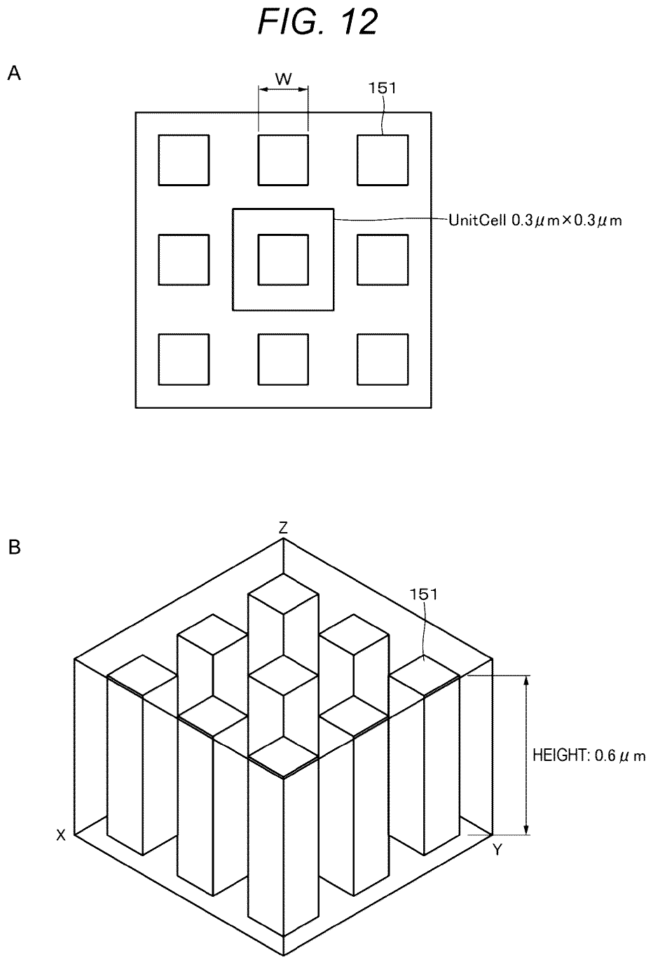

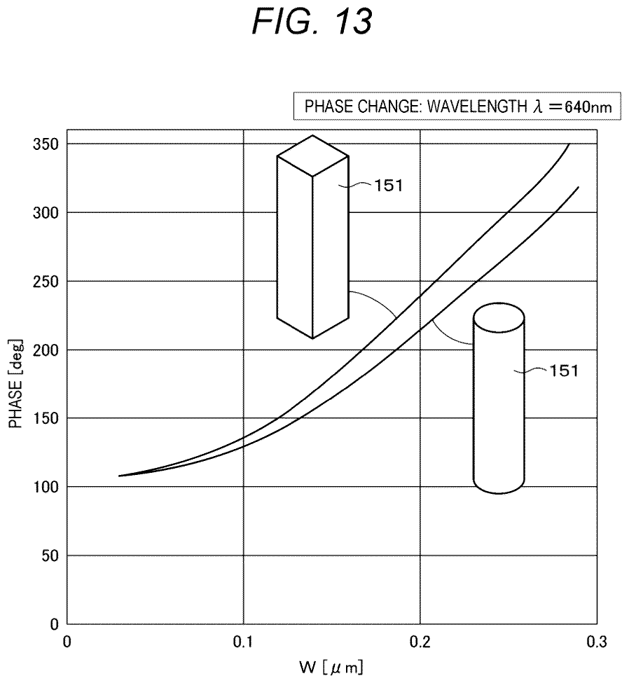

As illustrated in FIGS. 11A, 11B, 12A, 12B, and 13, the phase change amount can be changed in a manner that depends on the in-plane shape, diameter, height, or the like of the nanostructures 151. In a case where the metalens formation region (nanostructure formation region 15RE) is large, a parameter that achieves a phase change amount of 360 deg is generally selected. Accordingly, the height of the nanostructures 151 tends to be high, and the aspect ratio tends to be large. Therefore, there is a possibility that the fabrication of the nanostructure 151 becomes difficult.

On the other hand, when the size of the subpixel 10 is less than or equal to 10 μm, the metalens formation region (nanostructure formation region 15RE) becomes smaller, and the required lens height also decreases. Accordingly, the phase change amount designed on the basis of the curved lens shape is less likely to reach 360 deg, and the nanostructures 151 tend to be lower in height than the typical metalens 152. It is therefore possible to reduce the difficulty of fabrication of the nanostructures 151.

### Method for Manufacturing Display Device 101

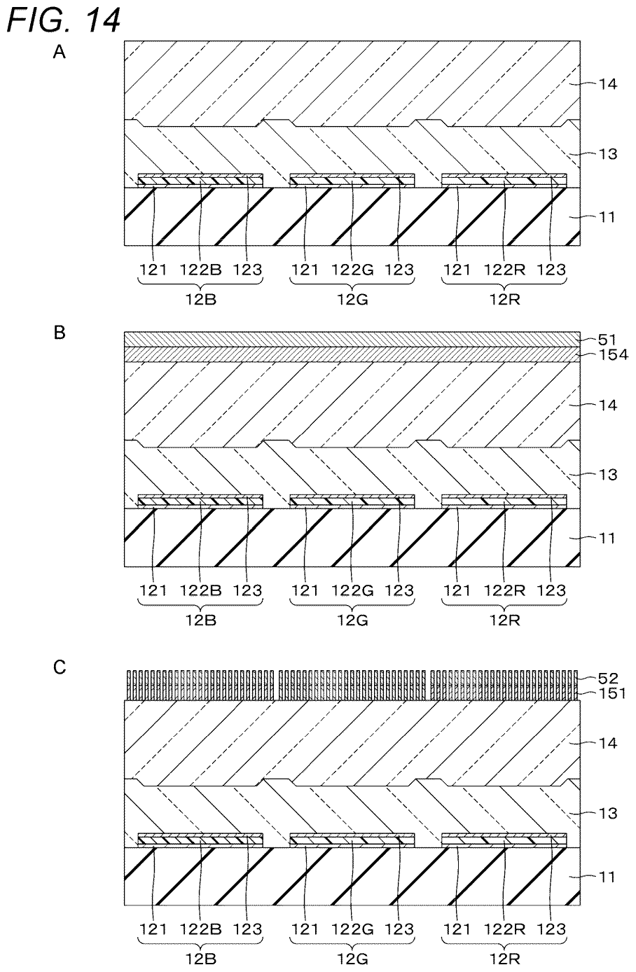

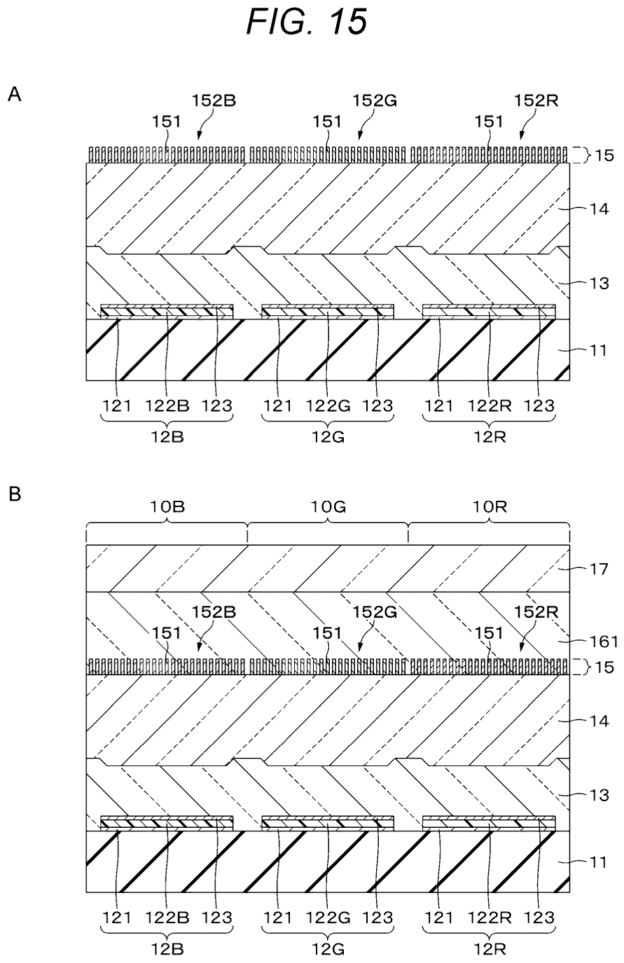

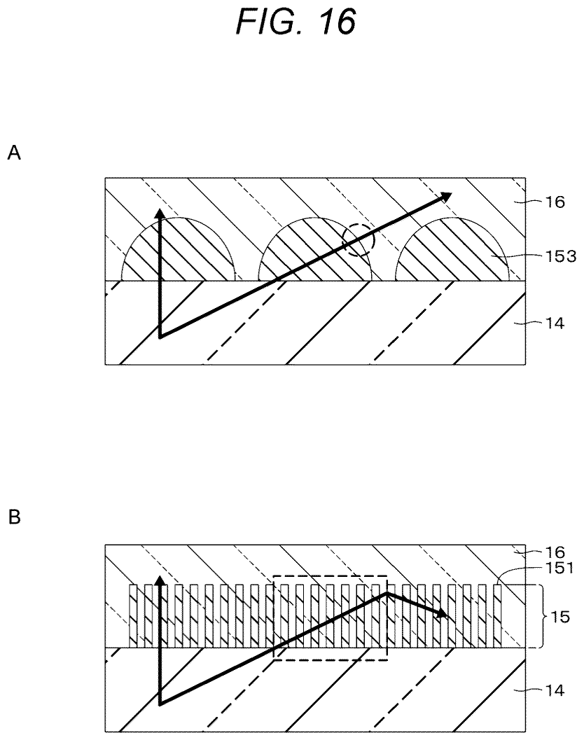

Hereinafter, an example of a method for manufacturing the display device 101 according to the first embodiment will be described with reference to FIGS. 14A, 14B, and 14C, 15A, and 15B.

First, a metal layer and a metal oxide layer are sequentially formed on the first surface of the drive substrate 11 by, for example, a sputtering method, and then the metal layer and the metal oxide layer are patterned using, for example, a photolithography technique and an etching technique. The plurality of first electrodes 121 is thus formed on the first surface of the drive substrate 11.

Next, the hole injection layer, the hole transport layer, the red organic light-emitting layer, the electron transport layer, and the electron injection layer are stacked in this order on the first surface of the plurality of first electrodes 121 and the first surface of the drive substrate 11 by, for example, a vapor deposition method to form the OLED layer 122R. Next, the second electrode 123 is formed on the first surface of the OLED layer 122R by, for example, a vapor deposition method or a sputtering method.

Next, the first protective layer is formed on the first surface of the second electrode 123 by, for example, a CVD method. Next, the OLED layer 122R, the second electrode 123, and the first protective layer are processed by, for example, a photolithography technique and a dry etching technique. The plurality of light-emitting elements 12R is thus formed on the first surface of the drive substrate 11.

Next, the plurality of light-emitting elements 12G and the plurality of light-emitting elements 12B are formed on the first surface of the drive substrate 11 through a procedure similar to the formation process of the light-emitting elements 12R. The plurality of light-emitting elements 12G and the plurality of light-emitting elements 12B are thus formed on the first surface of the drive substrate 11.

Next, the second protective layer is formed to cover the plurality of light-emitting elements 12 by, for example, a CVD method. As a result, the protective layer 13 is formed by the first protective layer and the second protective layer.

Next, as illustrated in FIG. 14A, the optical control layer 14 is formed on the first surface of the protective layer 13 by, for example, a CVD method or a vapor deposition method. As a result, the first surface of the protective layer 13 is planarized. Next, as illustrated in FIG. 14B, a high dielectric material layer 154 is formed on the first surface of the optical control layer 14 by, for example, a CVD method or a vapor deposition method, and then a resist is applied onto the first surface of the high dielectric material layer 154 to form a resist layer 51. Next, as illustrated in FIG. 14C, the resist layer 51 is processed by, for example, a photolithography technique to form a resist pattern 52, and then the high dielectric material layer 154 is etched through the resist pattern 52. Thereafter, the resist pattern 52 is removed. As a result, as illustrated in FIG. 15A, the plurality of nanostructures 151 is formed on the first surface of the optical control layer 14. That is, the plurality of metalenses 152R, the plurality of metalenses 152G, and the plurality of metalenses 152B are formed on the first surface of the optical control layer 14.

Next, as illustrated in FIG. 15B, a curable resin 161 is applied onto the first surface of the optical control layer 14 having the plurality of nanostructures 151 formed thereon to cover the plurality of nanostructures 151, and then the cover layer 17 such as a glass substrate is placed on the curable resin 161. The curable resin 161 includes, for example, at least one selected from a group consisting of a thermosetting resin, an ultraviolet curable resin, and the like. Next, for example, heat is applied to the curable resin 161 or ultraviolet rays are applied to the curable resin 161 to cure the curable resin 161. As a result, the optical control layer 14 having the plurality of nanostructures 151 formed thereon and the cover layer 17 are bonded together with the protective layer 16 interposed therebetween, the protective layer 16 being formed as a result of curing the curable resin 161. Through the above, the display device 101 illustrated in FIG. 5 is obtained.

### Operations and Effects

In the display device 101 according to the first embodiment, the ratio (L/D) of the distance L between the light-emitting element 12 and the metamaterial 15 to the size D of the subpixel 10 is greater than or equal to 0.2 and less than or equal to 1.8. Accordingly, as illustrated in FIG. 8A, the light emitted from the light-emitting element 12 at a wide angle is bent and focused in the frontal direction by the metalens 152. Therefore, the effect of the metalens 152 in improving the frontal luminance is enhanced.

Since the protective layer 16 covers the nanostructures 151, it is possible to make the nanostructures 151 less prone to collapse due to an external impact. It is therefore possible to suppress a change in phase information applied to light by the metalens 152, and it is possible to suppress a decrease in performance of the metalens 152. Furthermore, since the plurality of nanostructures 151 and the protective layer 16 covering the nanostructures 151 are different in refractive index, it is possible to protect the nanostructures 151 while maintaining a function as an optical element of the nanostructures 151.

It is possible to change, only by changing at least one of the arrangement, shape, height, or the like of the nanostructures (meta-atoms) 151, the characteristics of the metalens 152, making the design flexibility higher. The metalens 152 may reproduce a phase change when passing through the curved shape of the lens in the vertical direction. Herein, an existing lens (for example, an existing on-chip lens or the like) having a convex surface, a concave surface, or the like, which is not the metalens 152, is simply represented as “lens”.

As illustrated in FIGS. 10A, 10B, and 10C, since the curved shape of the lens (for example, an existing on-chip lens or the like) is reproduced by the arrangement, shape, height, and the like of the nanostructures 151, a lens with any desired shape can be formed by the nanostructures 151. This increases the design flexibility of the lens with fabrication taken into consideration. Furthermore, the nanostructures 151 may have a binary structure, and in this case, the nanostructures 151 that function as a lens can be fabricated by a single photolithography process.

Any desired lens shape can be designed by arranging the nanostructures 151. For example, not only the perfectly circular lens illustrated in FIG. 6A but also the elliptical lens illustrated in FIG. 7 can be designed.

The phase of the metalens 152 is preferably designed on the basis of phase information when light passes through the lens vertically. In this case, as illustrated in FIG. 16B, light obliquely incident on the lens is out of the design warranty, and it is difficult for metalens 152 to function as a lens for obliquely incident light. Therefore, light obliquely incident on adjacent subpixels 10 is less prone to be extracted to the front, and as a result, color mixing between the adjacent subpixels 10 is suppressed. On the other hand, as illustrated in FIG. 16A, an existing lens 153 functions as the lens 153 even for light obliquely incident on the lens 153, so that light obliquely incident on the adjacent subpixels 10 is also extracted to the front. Therefore, there is a possibility that color mixing occurs between the adjacent subpixels 10.

### Modifications

### Modification 1

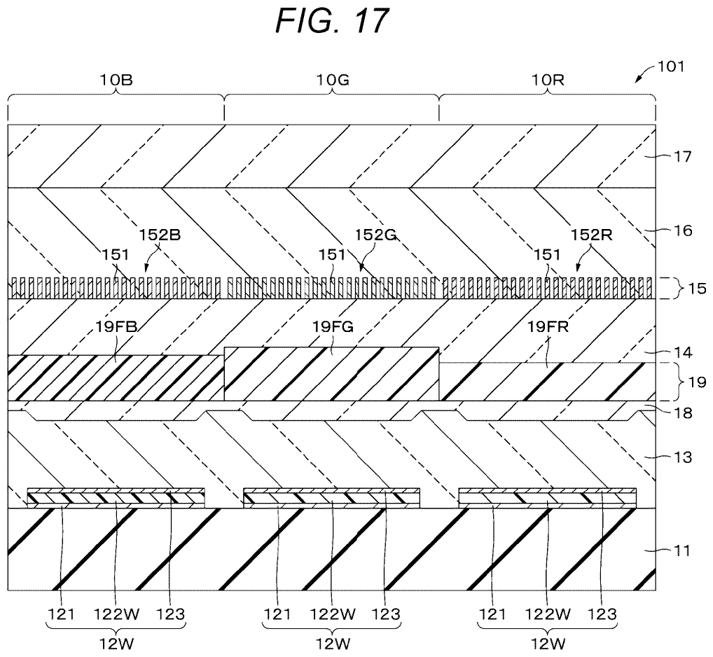

In the first embodiment, the example where the display device 101 includes the three-color light-emitting elements 12R, 12G, and 12B has been described, but the configuration of the display device 101 is not limited to such an example. For example, as illustrated in FIG. 17, the display device 101 may include light-emitting elements 12W instead of the three-color light emitting elements 12R, 12G, and 12B, and may further include a planarization layer 18 and a color filter 19.

### Light-Emitting Element 12W

The light-emitting element 12W can emit white light. The light-emitting element 12W is a white OLED element, and can emit white light under the control of the drive circuit and the like. The light-emitting element 12W is similar to the light-emitting element 12R except that an OLED layer 122W is provided instead of the OLED layer 122R.

The OLED layer 122W can emit white light. The OLED layer 122W may be an OLED layer including a single-layer light-emitting unit, an OLED layer including a two-layer light-emitting unit (tandem structure), or an OLED layer having a structure other than these structures. The OLED layer including a single-layer light-emitting unit has a configuration where a hole injection layer, a hole transport layer, a red light-emitting layer, a light-emitting separation layer, a blue light-emitting layer, a green light-emitting layer, an electron transport layer, and an electron injection layer are stacked in this order from the first electrode 121 toward the second electrode 123, for example. The OLED layer including a two-layer light-emitting unit has a configuration where a hole injection layer, a hole transport layer, a blue light-emitting layer, an electron transport layer, a charge generation layer, a hole transport layer, a yellow light-emitting layer, an electron transport layer, and an electron injection layer are stacked in this order from the first electrode 121 toward the second electrode 123, for example.

### Planarization Layer 18

The planarization layer 18 covers the first surface of the protective layer 13 to planarize the first surface of the protective layer 13. The planarization layer 18 includes, for example, an inorganic material or a polymer resin. As the inorganic material, a material similar to the inorganic material of the protective layer 13 can be exemplified. As the polymer resin, a material similar to the polymer resin of the protective layer 13 can be exemplified.

### Color Filter 19

The color filter 19 is provided above the plurality of light-emitting elements 12W. More specifically, the color filter 19 is provided on the first surface of the planarization layer 18. The color filter 19 includes, for example, a plurality of red filter portions 19FR, a plurality of green filter portions 19FG, and a plurality of blue filter portions 19FB. Note that, in the following description, the red filter portions 19FR, the green filter portions 19FG, and the blue filter portions 19FB may be collectively referred to as filter portion 19F unless otherwise distinguished.

The plurality of filter portions 19F is arranged two-dimensionally in the in-plane direction. Herein, the in-plane direction refers to an in-plane direction relative to the first surface of the drive substrate 11. Each filter portion 19F is provided above the corresponding light-emitting element 12W. The red filter portion 19FR and the light-emitting element 12W constitute the subpixel 10R, the green filter portion 19FG and the light-emitting element 12W constitute the subpixel 10G, and the blue filter portion 19fB and the light-emitting element 12W constitute the subpixel 10B.

The red filter portion 19FR transmits red light out of the white light emitted from the light-emitting element 12W but absorbs light other than the red light. The green filter portion 19FG transmits green light out of the white light emitted from the light-emitting element 12W but absorbs light other than the green light. The blue filter portion 19FB transmits blue light out of the white light emitted from the light-emitting element 12W but absorbs light other than the blue light.

The red filter portion 19FR includes, for example, a red color resist. The green filter portion 19FG includes, for example, a green color resist. The blue filter portion 19FB includes, for example, a blue color resist.

### Modification 2

In Modification 1 described above, the example where the light-emitting elements 12W are provided instead of the three-color light-emitting elements 12R, 12G, and 12B has been described, but the configuration including the three-color light-emitting elements 12R, 12G, and 12B may further include the planarization layer 18 and the color filter 19. In this case, the color purity of the display device 101 can be improved.

The red filter portion 19FR is provided above the light-emitting element 12R, the green filter portion 19FG is provided above the light-emitting element 12G, and the blue filter portion 19FB is provided above the light-emitting element 12B.

### Modification 3

In Modification 1 described above, the example where the OLED layer 122W and the second electrode 123 are divided between the adjacent subpixels 10 to be provided individually for each subpixel 10 has been described, but the configuration of the light-emitting element 12W is not limited to such an example. For example, the OLED layer 122W and the second electrode 123 may be provided continuously across the plurality of light-emitting elements 12W in the display region RE1, and may be shared by the plurality of light-emitting elements 12W in the display region RE1.

### 2 Second Embodiment

### Configuration of Display Device 102

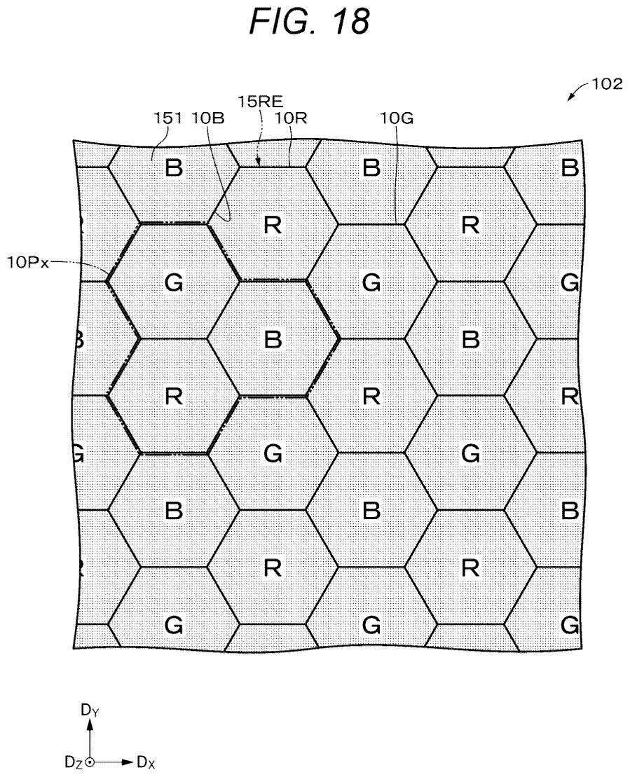

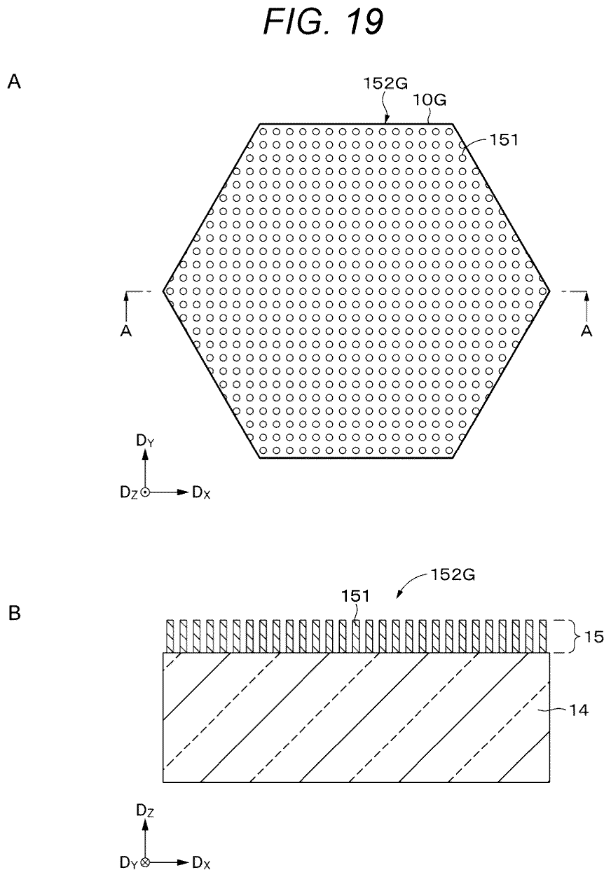

FIG. 18 is an enlarged plan view illustrating a part of a display region RE1 of a display device 102 according to a second embodiment. FIG. 19A is a plan view of a metalens 152G of a subpixel 10G. FIG. 19B is a cross-sectional view taken along line A-A in FIG. 19A. The display device 102 is different from the display device 101 (see FIGS. 2 and 6A) according to the first embodiment in that the plurality of nanostructures 151 is provided substantially across the entire subpixel 10 in plan view, that is, the nanostructure formation region 15RE is set substantially across the entire subpixel 10.

### Operations and Effects

In the display device 101 according to the first embodiment, since the plurality of nanostructures 151 is not provided at the peripheral edge portion of the subpixel 10 in plan view, there is a possibility that the ability to extract light decreases at the peripheral edge portion of the subpixel 10.

On the other hand, in the display device 102 according to the second embodiment, since the plurality of nanostructures 151 is provided substantially across the entire subpixel 10 in plan view, the area utilization efficiency (ratio of the formation region of the metalens 152 to the area of the subpixel 10) can be about 100%. It is therefore possible even for the peripheral edge portion of the subpixel 10 to increase the light extraction efficiency. Accordingly, the frontal luminance can be improved as compared with the display device 101 according to the first embodiment.

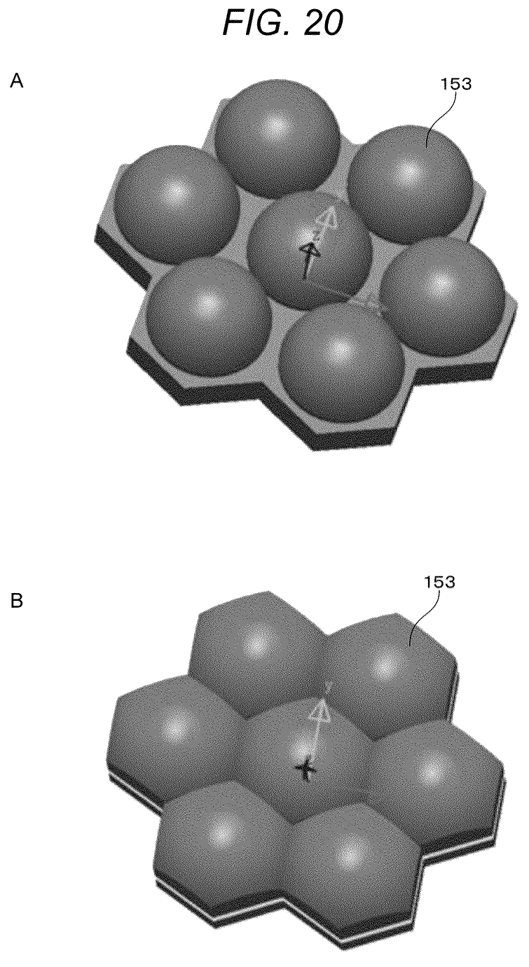

It is considered that the configuration where the plurality of nanostructures 151 is provided substantially across the entire subpixel 10 in plan view can be replaced with a configuration obtained by changing a lens array configuration with a gap provided between the lenses 153 (see FIG. 20A) to a lens array configuration with no gap provided between the lenses 153 (see FIG. 20B). The configuration with no gap provided between the lenses 153, however, causes a curved surface having a steep V-shaped cross section to be formed in an area between the lenses 153; therefore, there is a possibility that the lens 153 becomes difficult to fabricate and difficult to form in a desired shape.

On the other hand, in the metalens 152 according to the second embodiment, the nanostructures (meta-atoms) 151 having a pillar shape or the like are merely arranged two-dimensionally; therefore, it is easy to reproduce the phase pattern corresponding to the curved surface (see FIG. 20 B) having a V-shaped cross section as described above.

### 3 Third Embodiment

### Configuration of Display Device 103

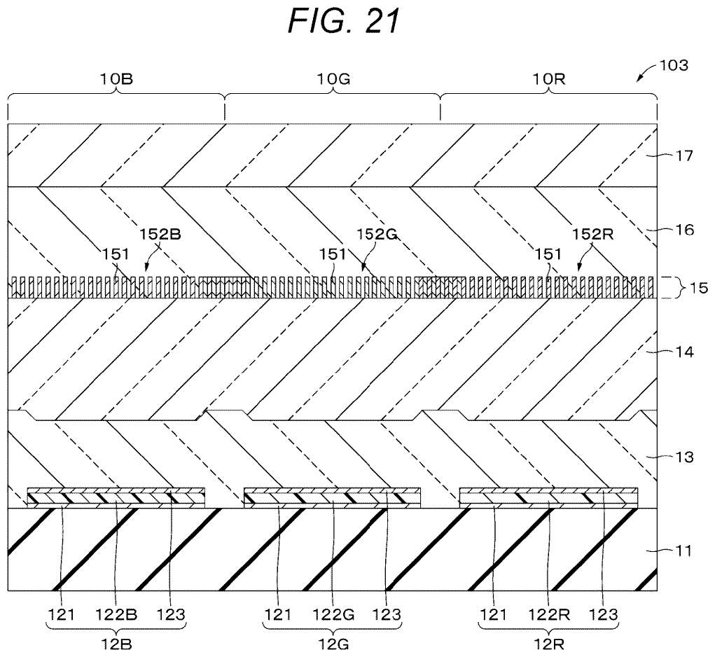

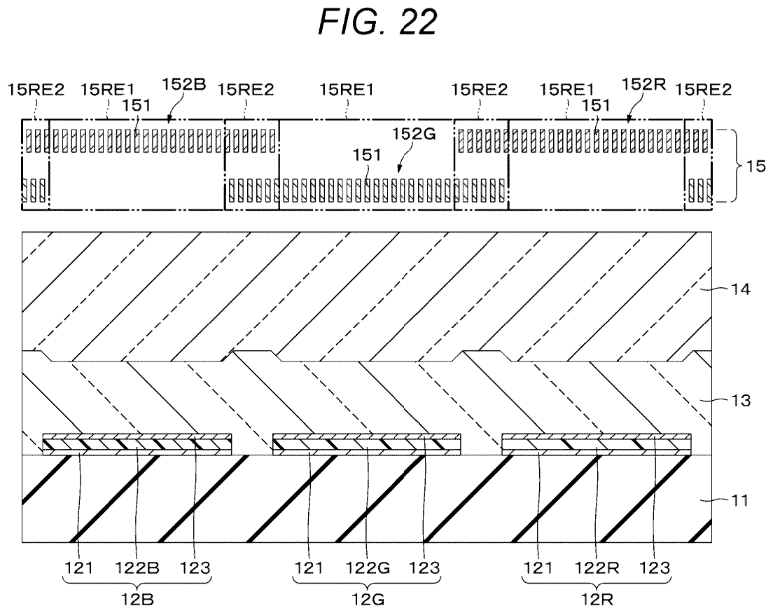

FIG. 21 is a cross-sectional view of a display device 103 according to a third embodiment. FIG. 22 is an exploded cross-sectional view for describing a configuration of metalenses 152R, 152G, and 152B. The display device 103 is different from the display device 101 (see FIGS. 2 and 5) according to the first embodiment in that the peripheral edge portions of adjacent metalenses 152 overlap in plan view.

### Metalenses 152R, 152G, and 152B

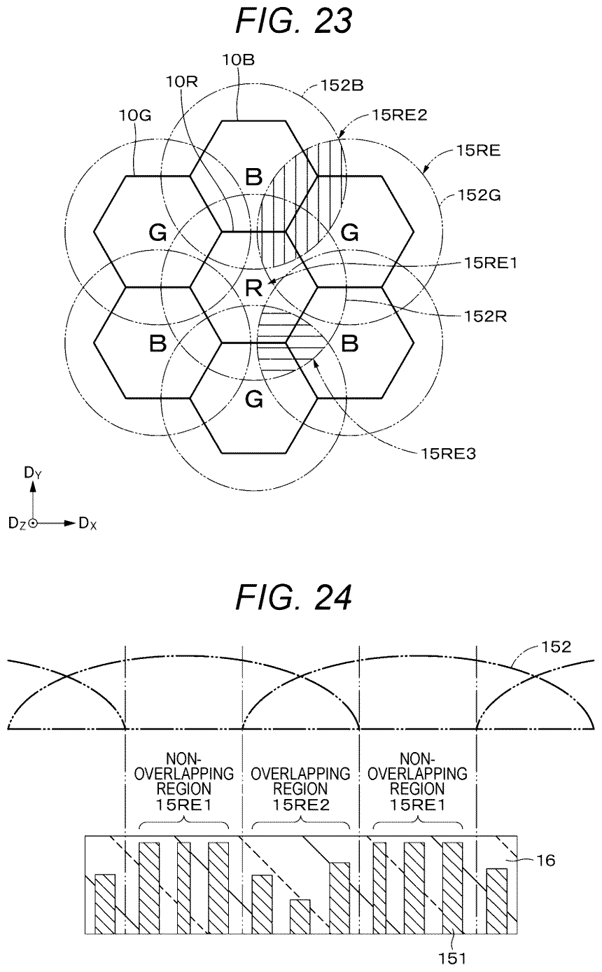

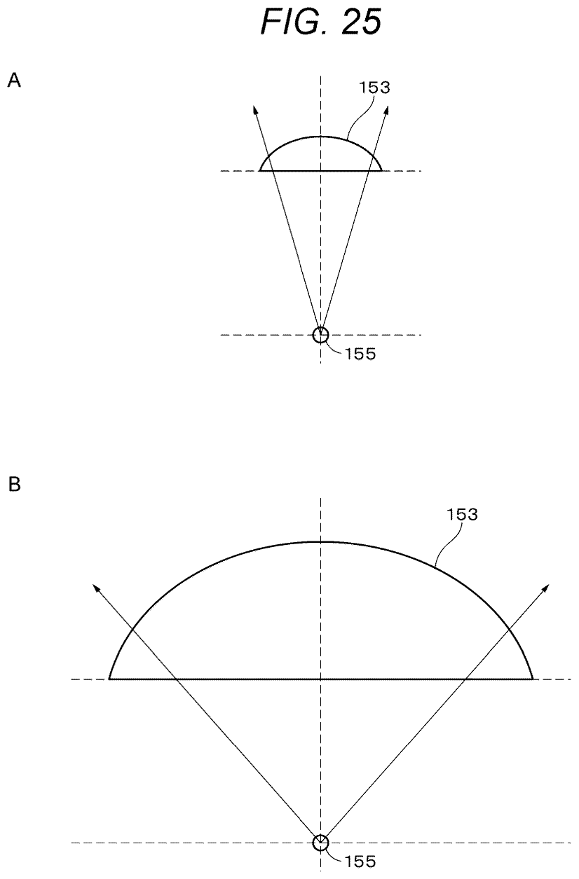

FIG. 23 is a plan view for describing the configuration of the metalenses 152R, 152G, and 152B. FIG. 24 is a cross-sectional view for describing the configuration of the metalenses 152R, 152G, and 152B. Note that, in FIG. 24, the metalens 152 is virtually represented by a geometric lens shape. Each of the metalenses 152R, 152G, and 152B is larger in size than the subpixel 10, and at least a part of the peripheral edge of each of the metalenses 152R, 152G, and 152B is located outside the peripheral edge of the corresponding subpixel 10. FIG. 23 illustrates an example where the peripheral edge of each of the metalenses 152R, 152G, and 152B is located outside the peripheral edge of the corresponding subpixel 10.

The metamaterial 15 has non-overlap region (non-overlapping region) 15RE1 where adjacent metalens 152 do not overlap, and an overlap region (overlapping region) 15RE2 where adjacent metalens 152 overlap.

Nanostructures 151 located in the non-overlap region 15RE1 of the metalens 152R function as the metalens 152R. Nanostructures 151 located in the non-overlap region 15RE1 of the metalens 152G function as the metalens 152G. Nanostructures 151 located in the non-overlap region 15RE1 of the metalens 152B function as the metalens 152B.

An overlap region 15RE2 of adjacent metalenses 152R and 152G functions as both the adjacent metalenses 152R and 152G. Nanostructures 151 located in the overlap region 15RE2 of the adjacent metalenses 152R and 152G form both the adjacent metalenses 152R and 152G.

An overlap region 15RE2 of adjacent metalenses 152G and 152B functions as both the adjacent metalenses 152G and 152B. Nanostructures 151 located in the overlap region 15RE2 of the adjacent metalenses 152G and 152B form both the adjacent metalenses 152G and 152B.

An overlap region 15RE2 of adjacent metalenses 152B and 152R functions as both the adjacent metalenses 152B and 152R. Nanostructures 151 located in the overlap region 15RE2 of the adjacent metalenses 152B and 152R form both the adjacent metalenses 152B and 152R.

An overlap region 15RE3 of adjacent metalenses 152R, 152G, and 152B functions as the three lenses of the adjacent metalenses 152R, 152G, and 152B. Nanostructures 151 located in the overlap region 15RE3 of the adjacent metalenses 152R, 152G, and 152B form the three lenses of the adjacent metalenses 152R, 152G, and 152B in the overlap region 15RE3.

The above-described function of the overlap region 15RE2 can be obtained, for example, by adjusting at least one of the arrangement, width, height, or the like of the nanostructures 151. For example, as illustrated in FIG. 24, the nanostructures 151 provided in the non-overlap region 15RE1 of the subpixel 10 (the central portion of the subpixel 10) may be different in height from the nanostructures 151 provided in the overlap region 15RE2 between the subpixels 10 (boundary between adjacent subpixels 10). The nanostructures 151 provided in the non-overlap region 15RE1 of the subpixel 10 (the central portion of the subpixel 10) may be approximately uniform in height. On the other hand, the nanostructures 151 provided in the overlap region 15RE2 of the subpixel 10 may vary in height in the in-plane direction.

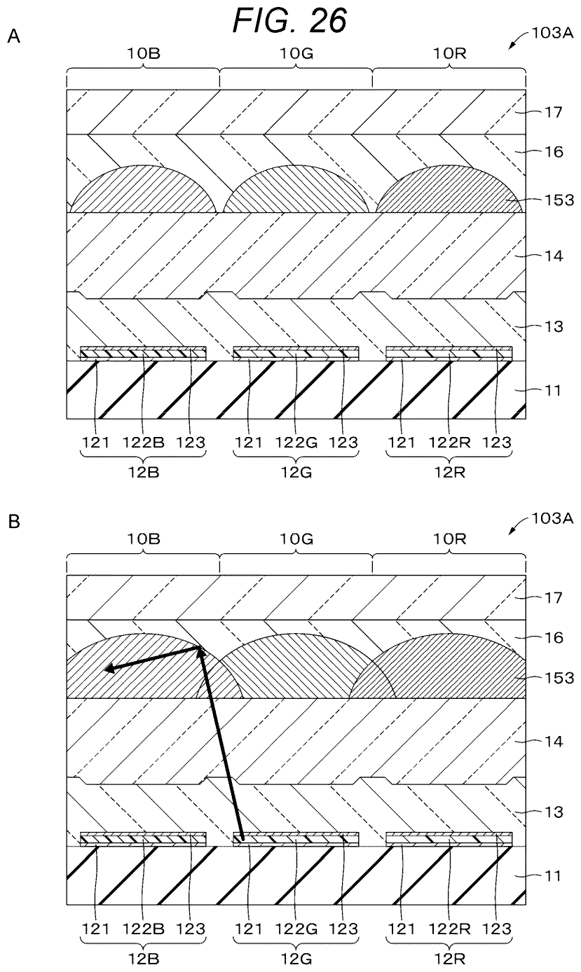

The structure of the overlap region 15RE2 described above is unique to the metalens 152. In general, as illustrated in FIGS. 25A and 25B, the larger the size of the lens 153 relative to a light source 155, the more light can be extracted to the front. However, for a three-dimensional curved lens 153, as illustrated in FIGS. 26A and 26B, an increase in the size of the lens 153 causes interference with the lenses 153 of adjacent subpixels 10, making it practically difficult to increase the size of the lens 153. On the other hand, since the metalens 152 controls the phase for each wavelength, the size of the lens 153 can be increased effectively.

### Operations and Effects

In the display device 103 according to the third embodiment, the metalens 152 can be formed larger than the region of the corresponding pixel (subpixel 10). That is, the area utilization efficiency (ratio of the formation region of the metalens 152 to the area of the subpixel 10) can be larger than 100%. It is therefore possible to improve the frontal luminance as compared with the display device 101 according to the first embodiment or the display device 102 according to the second embodiment.

It is possible to effectively increase, by designing the nanostructures 151 in the overlap region 15RE2 between adjacent subpixels 10 to cause the nanostructures 151 to act on light of both emission colors of the adjacent subpixels 10, the size of the metalens 152. Such a structure is not applicable to a lens such as a curved lens, but is applicable to the metalens 152 capable of controlling the phase for each wavelength.

### Modifications

### Modification 1

In the third embodiment, as illustrated in FIG. 23, the example where the overlap region 15RE3 in which three adjacent metalens 152R, 152G, and 152B overlap is formed has been described. Such an overlap region 15RE3, however, raises a possibility that the design constraints of the metalens 152 increases. Accordingly, the metamaterial 15 is preferably configured such that the formation of the overlap region 15RE3 is minimized or the overlap region 15RE3 is not formed, i.e., no more than three metalenses 152 overlap.

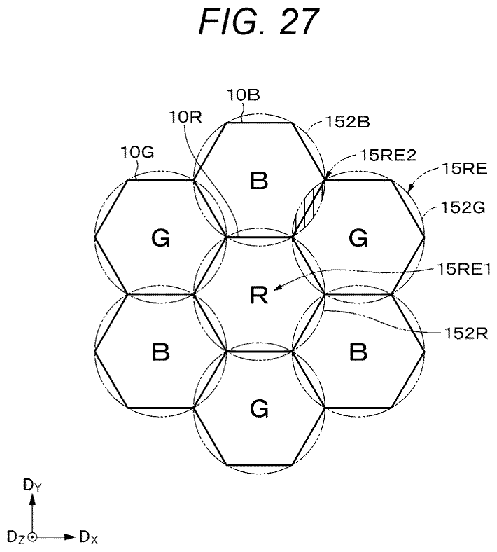

Examples of the arrangement of the metalenses 152 that minimizes the formation of the overlap region 15RE3 includes an arrangement where, as illustrated in FIG. 27, the metalenses 152 are arranged such that the peripheral edge of each metalens 152, that is, the peripheral edge of the nanostructure formation region 15RE, passes through a point where the corners of the three subpixels 10 meet.

Examples of the arrangement of the metalenses 152 that prevents the overlap region 15RE3 from being formed, that is, the arrangement of the metalenses 152 that forms the overlap region 15RE2 only by two overlapping metalenses 152 include the following.

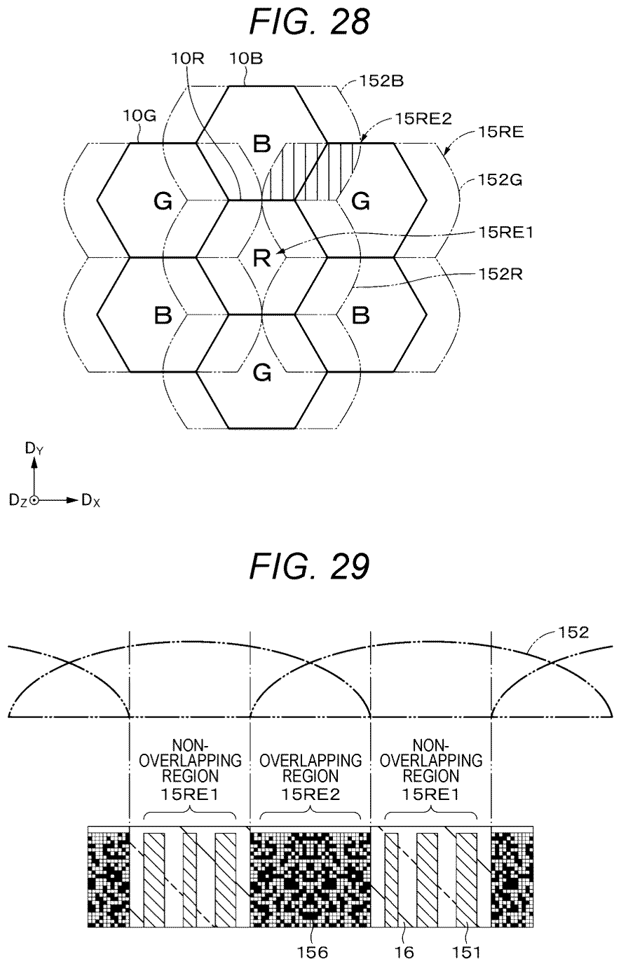

As illustrated in FIG. 28, the metalens 152, that is, the nanostructure formation region 15RE, is expanded in the horizontal direction (first direction) D_{X} relative to the subpixel 10 to cause metalenses 152 adjacent in the horizontal direction D_{X} to overlap. On the other hand, the metalens 152, that is, the nanostructure formation region 15RE, is not expanded in the vertical direction (second direction) D_{Y} relative to the subpixel 10 to prevent metalenses 152 adjacent in the vertical direction D_{Y} from overlapping.

The metalens 152, that is, the nanostructure formation region 15RE, is expanded in the vertical direction (second direction) D_{Y} relative to the subpixel 10 to cause metalenses 152 adjacent in the vertical direction D_{Y} to overlap. On the other hand, the metalens 152, that is, the nanostructure formation region 15RE, is not expanded in the horizontal direction (first direction) D_{X} relative to the subpixel 10 to prevent metalenses 152 adjacent in the horizontal direction D_{X} from overlapping.

The above-described configuration of the metalens 152 can make the area utilization efficiency higher than 100% even without designing the metalens 152 to accommodate three wavelength ranges (wavelength ranges of the subpixels 10R, 10G, and 10B).

### Modification 2

In the third embodiment, the example (see FIG. 24) where both the non-overlap region 15RE1 and the overlap region 15RE2 include a metasurface (the plurality of nanostructures 151) that is a two-dimensional metamaterial has been described, but the configuration of the overlap region 15RE2 and the non-overlap region 15RE1 is not limited to such an example.

For example, as illustrated in FIG. 29, the non-overlap region 15RE1 may include a metasurface (the plurality of nanostructures 151) that is a two-dimensional metamaterial, whereas the non-overlap region 15RE1 may include a three-dimensional metamaterial 156.

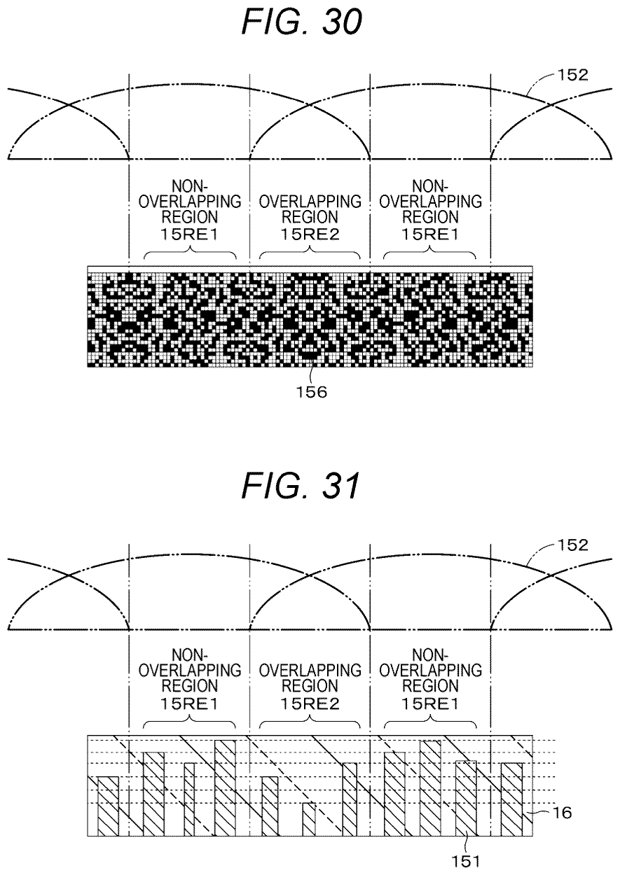

As illustrated in FIG. 30, both the non-overlap region 15RE1 and the overlap region 15RE2 may include the three-dimensional metamaterial 156.

### Modification 3

As illustrated in FIG. 31, the nanostructures 151 provided in the non-overlap region 15RE1 and the overlap region 15RE2 may have a plurality of specified heights.

### 4 Fourth Embodiment

### Configuration of Display Device 104

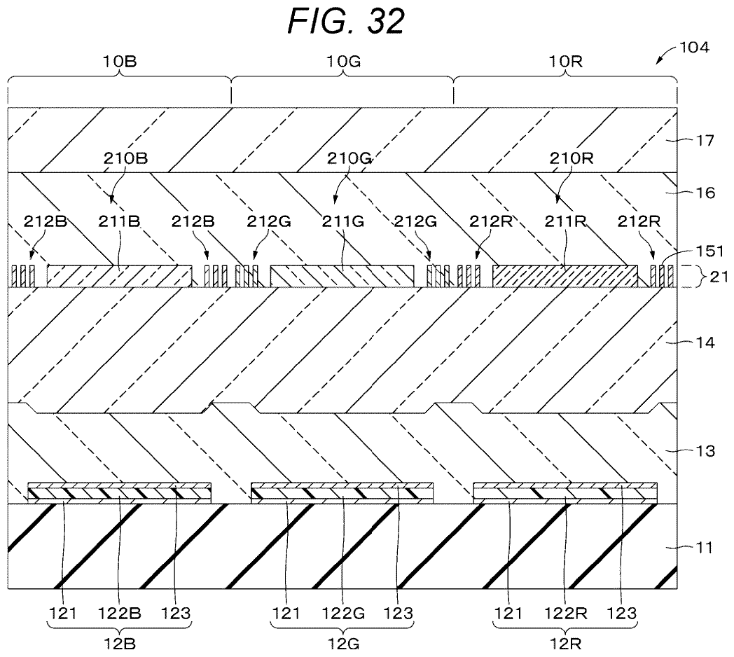

FIG. 32 is a cross-sectional view of a display device 104 according to a fourth embodiment. The display device 104 is different from the display device 101 according to the first embodiment in including a compound layer 21 instead of the metamaterial 15 (see FIG. 5).

### Compound Layer 21

The compound layer 21 includes a plurality of compound lenses 210R, a plurality of compound lenses 210G, and a plurality of compound lenses 210B. In the following description, the compound lenses 210R, 210G, and 210B may be collectively referred to as compound lens 210 unless otherwise distinguished.

### Compound Lenses 210R, 210G, 210B

The compound lens 210R can focus the light emitted from the light-emitting element 12R and incident from below. The compound lens 210G can focus the light emitted from the light-emitting element 12G and incident from below. The compound lens 210B can focus the light emitted from the light-emitting element 12B and incident from below. Each of the compound lenses 210R, 210G, and 210B may collimate the light incident from below and emit the light as parallel light (parallel light approximately perpendicular to the display surface).

The compound lenses 210R, 210G, and 210B may have a function corresponding to a lens having a geometric convex or concave surface. The configurations of the compound lenses 210R, 210G, and 210B may be different from each other or may be the same, but the configurations preferably vary in a manner that depends on the light incident from the light-emitting elements 12R, 12B, and 12G. For example, at least one of the arrangement, height, shape, or the like of the nanostructures 151 constituting the compound lenses 210R, 210G, and 210B may be different among the compound lenses 210R, 210G, and 210B.

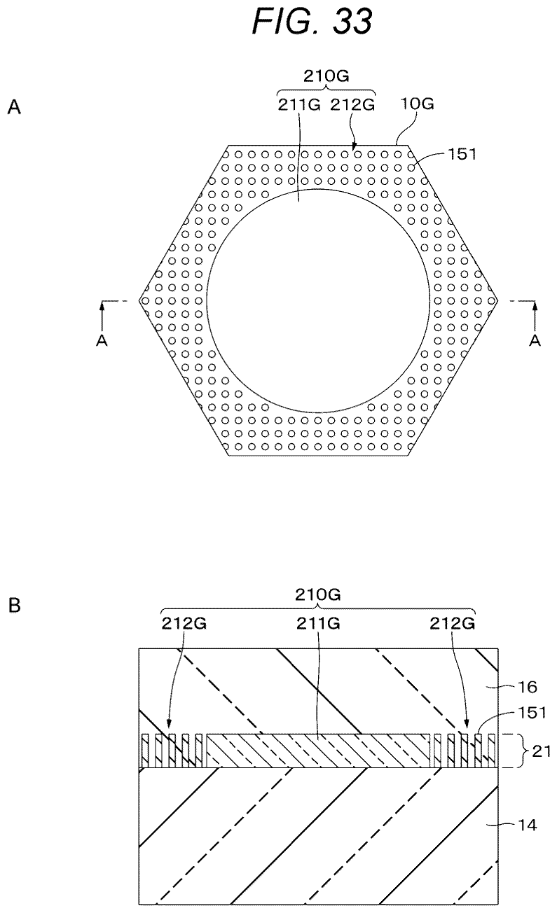

FIG. 33A is a plan view of the compound lens 210G of the subpixel 10G. FIG. 33B is a cross-sectional view taken along line A-A in FIG. 33A. Note that the compound lens 210R of the subpixel 10R and the compound lens 210B of the subpixel 10B may have a configuration substantially similar to that of the compound lens 210G of the subpixel 10G; therefore, the illustration of the compound lens 210R and compound lens 210B will be omitted.

The compound lens 210R is provided above the light-emitting element 12R. The compound lens 210R partially includes a metalens 212R. Specifically, the compound lens 210R includes a lens 211R and the metalens 212R provided above the light-emitting element 12R.

The compound lens 210G is provided above the light-emitting element 12G. The compound lens 210G partially includes a metalens 212G. Specifically, the compound lens 210G includes a lens 211G and the metalens 212G provided above the light-emitting element 12G.

The compound lens 210B is provided above the light-emitting element 12B. The compound lens 210B partially includes a metalens 212B. Specifically, the compound lens 210B includes a lens 211B and the metalens 212B provided above the light-emitting element 12B.

### Lenses 211R, 211G, 211B

The lenses 211R, 211G, and 211B can apply a substantially uniform phase change to light emitted upward from the light-emitting element 12R, the light-emitting element 12G, and the light-emitting element 12B, respectively. The lenses 211R, 211G, and 211B may each have a flat upper surface. Examples of the shape of the lenses 211R, 211G, and 211B include a cylindrical shape, a prismatic shape, and the like, but are not limited to such shapes. The lenses 211R, 211G, and 211B are different in refractive index from the protective layer 16. The lenses 211R, 211G, and 211B may be higher in refractive index than the protective layer 16, or the lenses 211R, 211G, and 211B may be lower in refractive index than the protective layer 16.

### Metalenses 212R, 212G, and 212B

The metalenses 212R, 212G, and 212B can apply a larger phase change to the light emitted upward from the light-emitting elements 12R, 12G, and 12B, respectively, than the lenses 211R, 211G, and 211B. Each of the metalens 212R, 212G, and 212B includes a plurality of nanostructures 151. The refractive index of the nanostructures 151 may be the same as or different from the refractive index of the lenses 211R, 211G, and 211B. The nanostructures 151 may be higher in refractive index than the lenses 211R, 211G, and 211B, or the nanostructures 151 may be lower in refractive index than the lenses 211R, 211G, and 211B.

The plurality of nanostructures 151 provided above the light-emitting element 12R is provided at the same height as the lens 211R (that is, on the first surface of the optical control layer 14), and is arranged two-dimensionally around the lens 211R to surround the lens 211R. The plurality of nanostructures 151 provided above the light-emitting element 12G is provided at the same height as the lens 211G (that is, on the first surface of the optical control layer 14), and is arranged two-dimensionally around the lens 211G to surround the lens 211G. The plurality of nanostructures 151 provided above the light-emitting element 12B is provided at the same height as the lens 211B (that is, on the first surface of the optical control layer 14), and is arranged two-dimensionally around the lens 211B to surround the lens 211B.

### Operations and Effects

In the display device 104 according to the fourth embodiment, the plurality of nanostructures (meta-atoms) 51 is arranged in a first region with a large phase change of each of the compound lenses 210R, 210G, and 210B, and the lenses 211R, 211G, and 211B, each having a flat upper surface, are each arranged in a second region with a small phase change of a corresponding one of the compound lenses 210R, 210G, and 210B (region with a smaller phase change than the first region). This configuration allows for a reduction in the number of nanostructures (meta-atoms) 51 as compared with a case where the metalens 152R, 152G, and 152B include the nanostructures 151. It is therefore possible to facilitate the fabrication of the compound lenses 210R, 210G, and 210B as compared with the fabrication of the metalenses 152R, 152G, and 152B in the first embodiment or the second embodiment.

### Modifications

### Modification 1

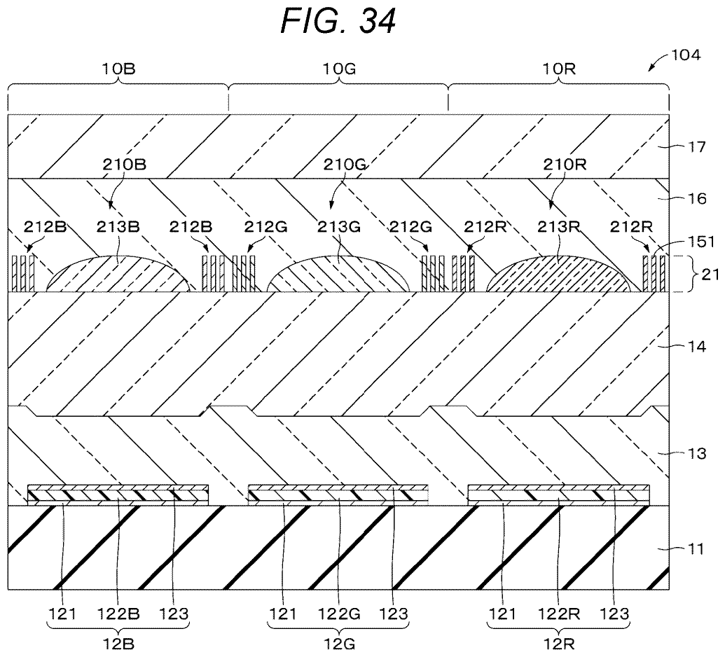

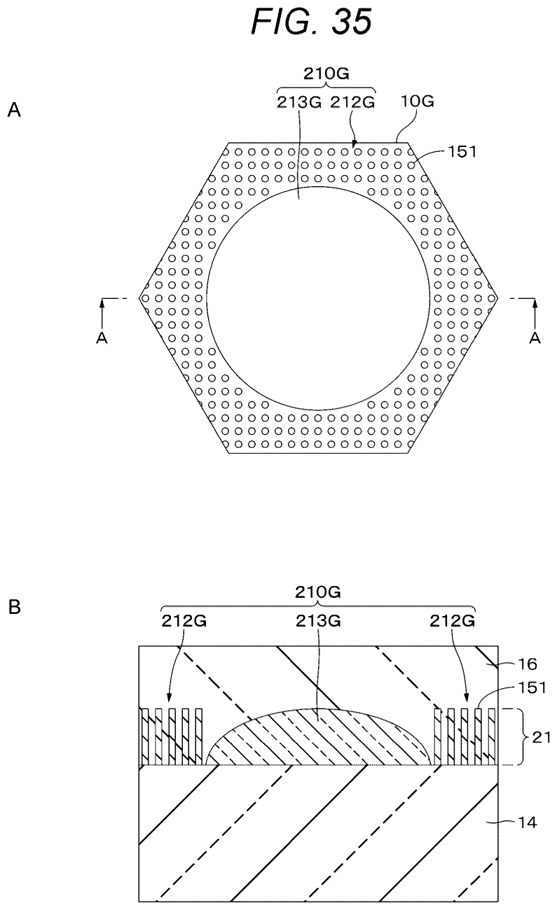

As illustrated in FIGS. 34, 35A, and 35B, the compound lenses 210R, 210G, and 210B may include lenses 213R, 213G, and 213B, each having a three-dimensional curved surface on the emission surface side, respectively, instead of the lenses 211R, 211G, and 211B (see FIGS. 32 and 33B), each having a flat upper surface on the emission surface side. In FIGS. 34 and 35B, an example where the curved surface is a convex surface protruding away from the light-emitting element 12 is illustrated, but the curved surface may be a concave surface curved toward the light-emitting element 12.

In Modification 2, the nanostructures (meta-atoms) 51 are arranged in a region with a large phase change of each of the subpixels 10R, 10G, and 10B, and the lenses 211R, 211G, and 211B, each having a three-dimensional curved surface, are each arranged in a region with a small phase change of a corresponding one of the subpixels 10R, 10G, and 10B. With this arrangement, effects similar to those of the fourth embodiment can be produced.

### Modification 2

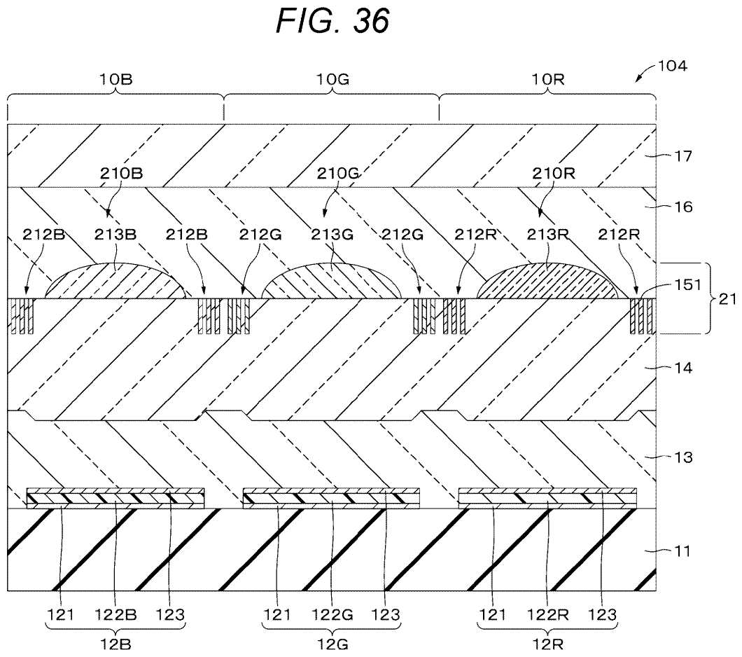

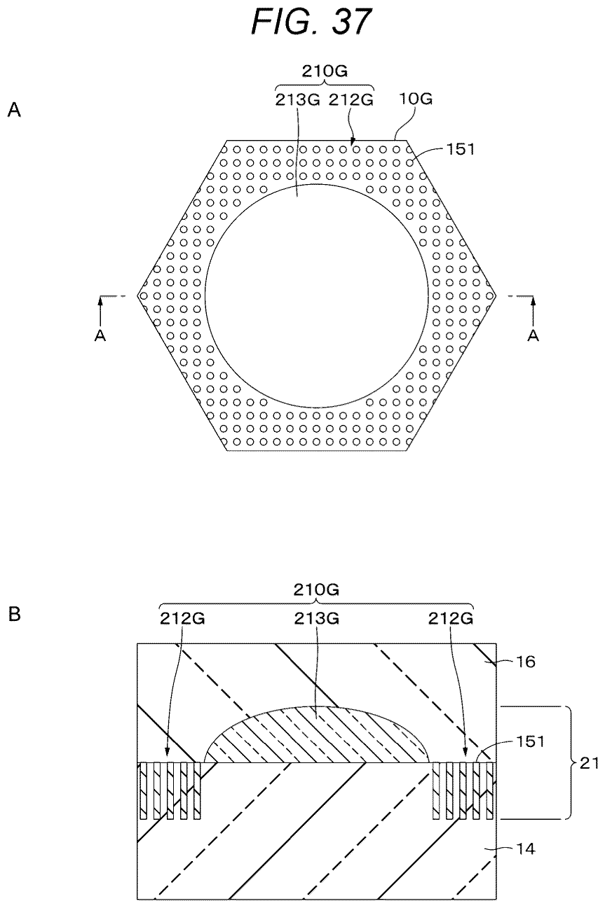

As Illustrated in FIGS. 36, 37A, and 37B, the plurality of nanostructures 151 may be provided at different heights (different positions in the thickness direction of the display device 104) from the plurality of lenses 213R, 213G, and 213B. Specifically, the plurality of nanostructures 151 may be provided at positions lower than the lenses 213R, 213G, and 213B. The plurality of nanostructures 151 may be embedded in the first surface side of the optical control layer 14. The plurality of nanostructures 151 may have their respective upper ends located flush with the first surface of the optical control layer 14.

The process of fabricating the plurality of nanostructures 151 and the plurality of lenses 213R, 213G, and 213B in Modification 2 is less likely to cause interference as compared with the process of fabricating the nanostructures 151 and the plurality of lenses 213R, 213G, and 213B in Modification 1. It is therefore possible to facilitate the fabrication of the plurality of nanostructures 151 and the plurality of lenses 213R, 213G, and 213B in Modification 2 as compared with the fabrication of the nanostructures 151 and the plurality of lenses 213R, 213G, and 213B in Modification 1.

In Modification 2, the example where the plurality of nanostructures 151 is provided at positions lower than the lenses 213R, 213G, and 213B has been described, but the plurality of nanostructures 151 may be provided at positions higher than the lenses 213R, 213G, and 213B.

In Modification 2, the example where the compound lenses 210R, 210G, and 210B include the lenses 213R, 213G, and 213B has been described, but the compound lenses 210R, 210G, and 210B may include the compound lenses 211R, 211G, and 211B.

### Modification 3

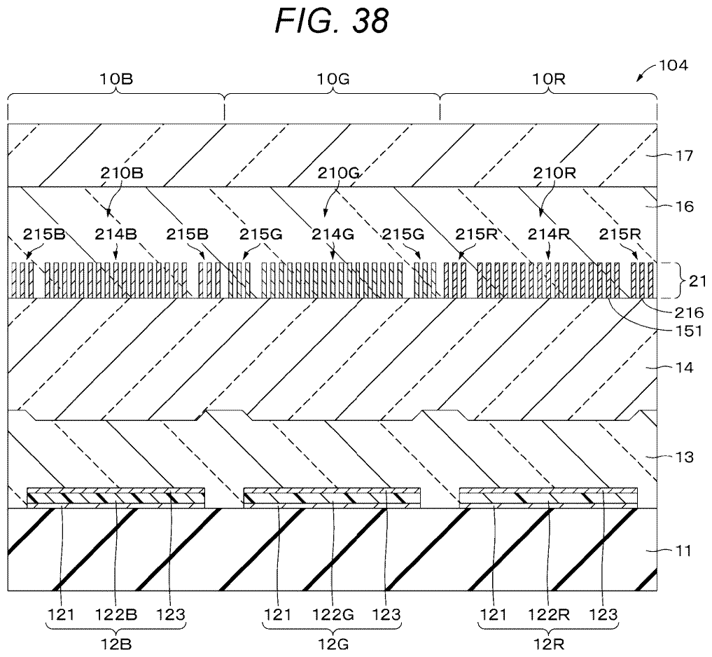

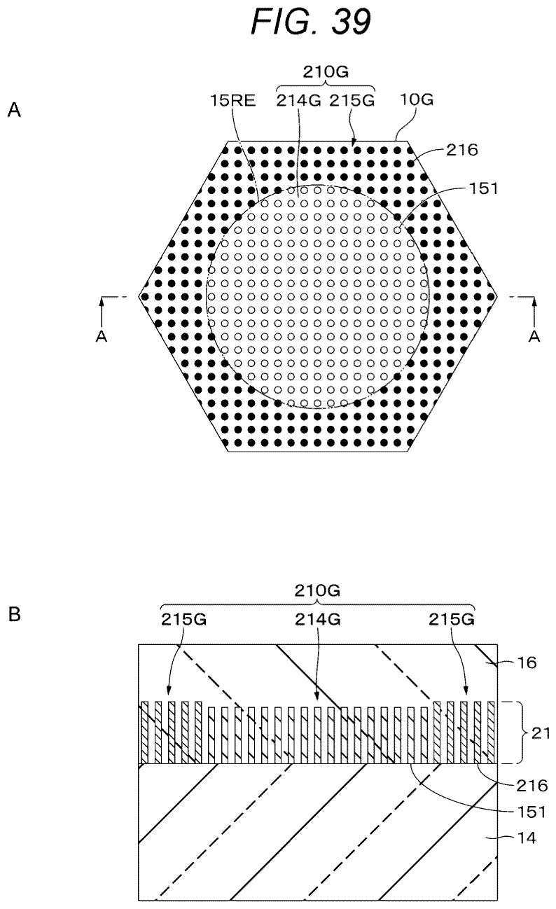

As illustrated in FIGS. 38, 39A, and 39B, the compound lens 210R may include a metalens 214R and a grating (diffraction grating) 215R provided above the light-emitting element 12R. The compound lens 210G may include a metalens 214G and a grating 215G provided above the light-emitting element 12G. The compound lens 210B may include a metalens 214B and a grating 215B provided above the light-emitting element 12B.

The grating 215R provided above the light-emitting element 12R is provided at the same height as the metalens 214R (that is, on the first surface of the optical control layer 14), and is arranged around the metalens 214R to surround the metalens 214R. The grating 215G provided above the light-emitting element 12G is provided at the same height as the metalens 214G (that is, on the first surface of the optical control layer 14), and is arranged around the metalens 214G to surround the metalens 214G. The grating 215B provided above the light-emitting element 12B is provided at the same height as the metalens 214B (that is, on the first surface of the optical control layer 14), and is arranged around the metalens 214B to surround the metalens 214B.

A lens such as a metalens using phase control exhibits characteristics through interference of phase changes from all lens positions. Therefore, to achieve a metalens with excellent characteristics, it is preferable to fabricate a lens outer peripheral portion that causes a large phase change with high accuracy. On the other hand, in the structure of the compound lenses 210R, 210G, and 210B of Modification 3, the central portion has a lens structure including the metalens 214R, 214G, and 214B, whereas the outer peripheral portion that causes a large phase change includes the gratings 215R, 215G, and 215B. With this structure, the gratings 215R, 215G, and 215B can individually have the ability to bend light at the outer peripheral portion; therefore, the effects of the structure of the compound lenses 210R, 210G, and 210B are readily exhibited.

In Modification 3, the example where the gratings 215R, 215G, and 215B and the metalens 214R, 214G, and 214B are provided at the same height has been described, but the gratings 215R, 215G, and 215B and the metalens 214R, 214G, and 214B may be provided at different heights. In this case, the gratings 215R, 215G, and 215B may be provided at positions higher than the metalens 214R, 214G, and 214B, or the gratings 215R, 215G, and 215B may be provided at positions lower than the metalens 214R, 214G, and 214B.

### 5 Fifth Embodiment

### Configuration of Display Device 105

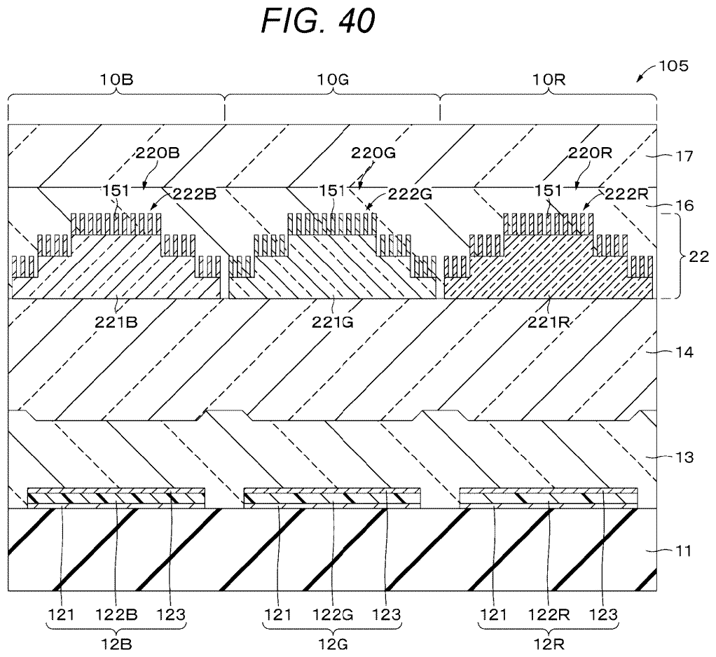

FIG. 40 is a cross-sectional view of a display device 105 according to a fifth embodiment. The display device 105 is different from the display device 101 according to the fourth embodiment in including a compound layer 22 instead of the compound layer 21.

### Compound Layer 22

The compound layer 22 is different from the compound layer 21 according to the fourth embodiment in including a plurality of compound lenses 220R, 220G, and 220B instead of the plurality of compound lenses 210R, 210G, and 210B. In the following description, the compound lenses 220R, 220G, and 220B may be collectively referred to as compound lens 220 unless otherwise distinguished.

### Compound Lenses 220R, 220G, 220B

The compound lens 210R includes a phase shifter (phase assist structure) 221R and a metalens 222R provided above the light-emitting element 12R. The compound lens 210G includes a phase shifter (phase assist structure) 221G and a metalens 222G provided above the light-emitting element 12G. The compound lens 210B includes a phase shifter (phase assist structure) 221B and a metalens 222B provided above the light-emitting element 12B.

### Phase Shifters 221R, 221G, and 221B

The phase shifters 221R, 221G, and 221B are phase assist structures transparent to light emitted from the light-emitting elements 12R, 12G, and 12B, respectively. The phase shifters 221R, 221G, and 221B are preferably transparent to visible light. The phase shifters 221R, 221G, and 221B can apply a phase change to light emitted upward from the light-emitting element 12R, the light-emitting element 12G, and the light-emitting element 12B, respectively. The phase shifters 221R, 221G, and 221B can assist in the phase changes of the metalens 222R, 222G, and 222B, respectively.

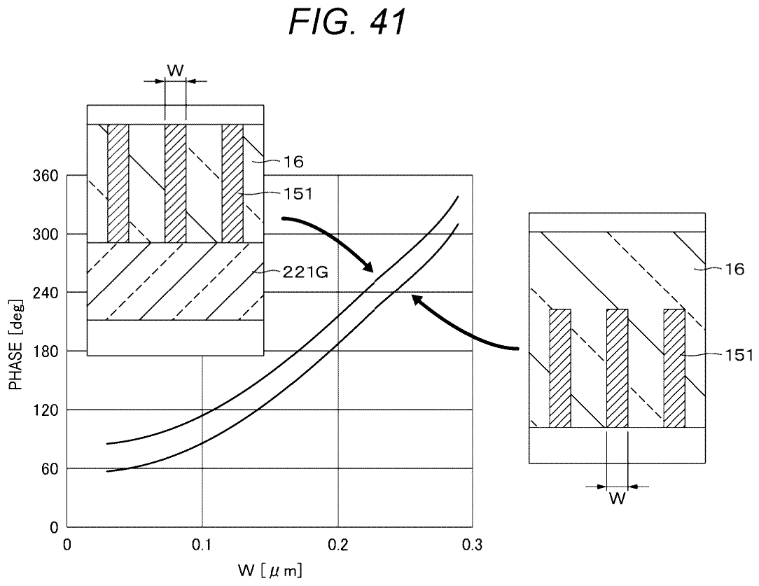

FIG. 41 is a graph showing a difference in phase modulation amount with or without the phase shifter 221G. As shown in FIG. 41, it is possible to apply, by providing the phase shifter 221G under the nanostructures (meta-atoms) 151, a substantially uniform phase change to the nanostructures (meta-atoms) 151 regardless of the dimension W of the nanostructures (meta-atoms) 151.

The phase shifters 221R, 221G, and 221B may each have a stepped upper surface. The phase shifters 221R, 221G, and 221B are different in refractive index from the protective layer 16. The phase shifters 221R, 221G, and 221B may be higher in refractive index than the protective layer 16, or the phase shifters 221R, 221G, and 221B may be lower in refractive index than the protective layer 16.

### Metalenses 222R, 2122G, and 222B

The metalens 222R is provided on the upper surface of the phase shifter 221R. The metalens 222G is provided on the upper surface of the phase shifter 221G. The metalens 222B is provided on the upper surface of the phase shifter 221B.

FIG. 40 illustrates an example where the metalens 212R provided above the light-emitting element 12R is entirely provided on the phase shifter 221R, but the metalens 212R provided above the light-emitting element 12R may be partially provided on the phase shifter 221R. Similarly, the metalens 212G provided above the light-emitting element 12G is partially provided on the phase shifter 221G, and the metalens 212B provided above the light-emitting element 12B may be partially provided on the phase shifter 221B.

### Operations and Effects

In general, to yield a large phase change, the nanostructures (meta-atoms) 151 tends to have a dimension in the vertical direction (dimension in the frontal direction D_{Z}) larger than in-plane dimensions (dimensions in the horizontal direction D_{X} and the vertical direction D_{Y}). Therefore, the aspect ratio becomes large, and there is a possibility that the difficulty of fabrication of the nanostructures 151 increases.

Therefore, in the display device 105 according to the fifth embodiment, the phase shifters 221R, 221G, and 221B are provided to yield a rough phase change to a relatively large region. This eliminates the need for relying solely on the nanostructures (meta-atoms) 151 to achieve all phase changes, and it is therefore possible to reduce the difficulty of fabrication of the nanostructures (meta-atoms) 151.

### Modifications

### Modification 1

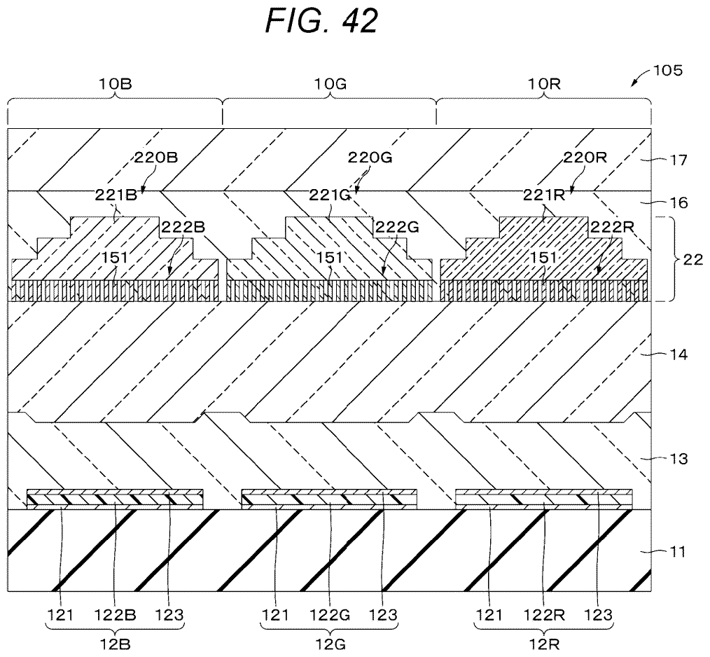

In the fifth embodiment, the example where the metalenses 212R, 212G, and 212B are provided on the phase shifters 221R, 221G, and 221B, respectively, has been described, but, as illustrated in FIG. 42, the phase shifters 221R, 221G, and 221B may be provided on the metalenses 212R, 212G, and 212B, respectively.

### Modification 2

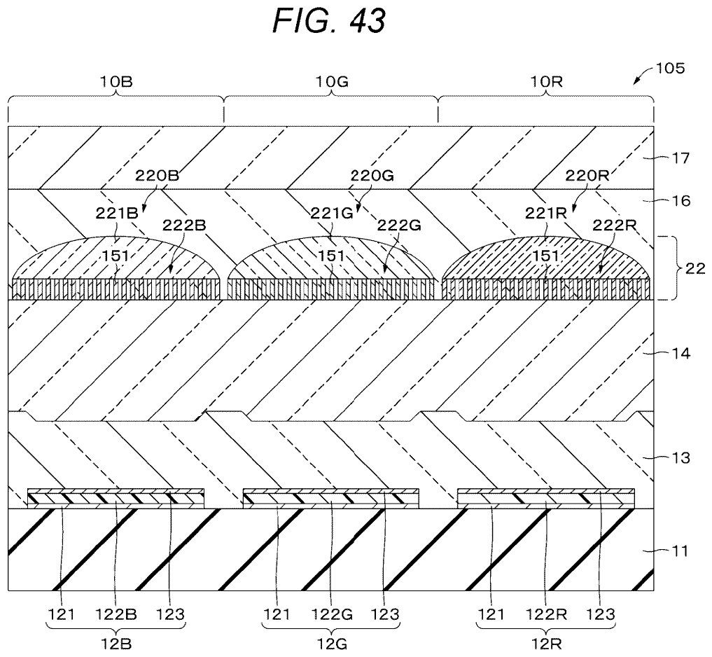

In the fifth embodiment, the example where the phase shifters 221R, 221G, and 221B each have a stepped upper surface has been described, but the upper surface of each of the phase shifters 221R, 221G, and 221B may have a shape other than the stepped shape. Examples of the shape other than the stepped shape include a curved surface illustrated in FIG. 43. FIG. 43 illustrates an example where the curved surface is a convex surface protruding away from the light-emitting element 12, but the curved surface may be a concave surface curved toward the light-emitting element 12.

### 6 Sixth Embodiment

### Configuration of Display Device 106

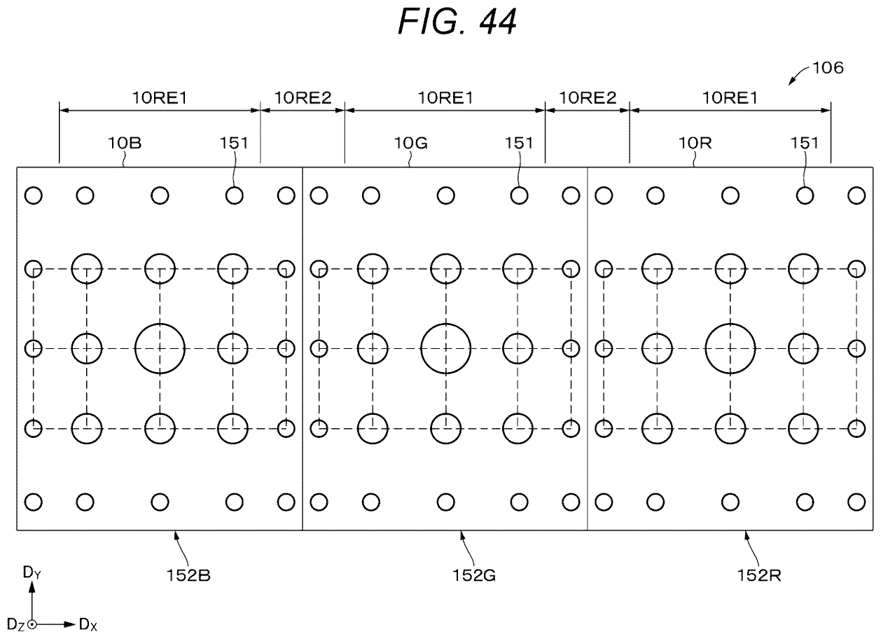

FIG. 44 is a plan view of a metasurface of a display device 106 according to a sixth embodiment. For the display device 102 according to the second embodiment, the example where the nanostructures (meta-atoms) 151 are uniformly arranged at equal intervals across the display region RE1 has been described, but the arrangement of the plurality of nanostructures (meta-atoms) 151 is not limited to such an example. For the display device 106 according to the sixth embodiment, an example where the nanostructures (meta-atoms) 151 are not uniformly arranged at equal intervals across the display region RE1 will be described.

The display device 106 includes a uniform arrangement region 10RE1 where a distance between the nanostructures (meta-atoms) 151 is constant, and a non-uniform arrangement region 10RE2 where the distance between the nanostructures (meta-atoms) 151 is not constant but varies. As illustrated in FIG. 44, the non-uniform arrangement region 10RE2 is preferably provided in a boundary region between adjacent subpixels 10. The nanostructures 151 may vary in width within the subpixel 10, as illustrated in FIG. 44. The distance between the nanostructures 151 in the non-uniform arrangement region 10RE2 may be greater or less than the distance between the nanostructures 151 in the uniform arrangement region 10RE1.

### Operations and Effects

It may be difficult to manufacture an integer number of nanostructures 151 at equal intervals across one subpixel 10 and another subpixel 10 adjacent to each other.

Since the display device 106 according to the sixth embodiment has the non-uniform arrangement region 10RE2, the distance between the nanostructures 151 can be adjusted in the non-uniform arrangement region 10RE2. Therefore, the formation of the nanostructures 151 is facilitated.

In particular, to obtain a metalens 152 with excellent light-focusing characteristics, a phase change at the outer peripheral portion of each subpixel 10 tends to become large. In a case where the non-uniform arrangement region 10RE2 is provided in the boundary region between the subpixels 10, it is easy to achieve continuous phase changes at the outer peripheral portion of the subpixel 10. It is therefore easy to improve the characteristics of the metalens 152.

### Modifications

### Modification 1

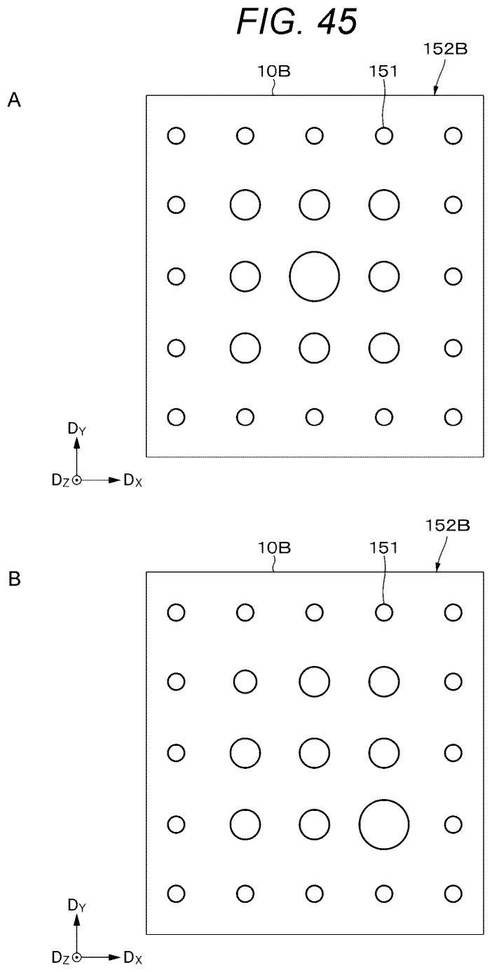

FIG. 45A is a plan view of a metalens 152B corresponding to a symmetric lens (non-decentered lens). FIG. 45B is a plan view of a metalens 152B corresponding to an asymmetric lens (decentered lens). For example, for the outer peripheral portion of a light-emitting device such as the display device 106, there is a case where it is desired to bend light in a desired direction rather than extracting light vertically. In such a case, it is possible to easily obtain, by changing the arrangement of the nanostructures 151 from a symmetric arrangement to an asymmetric arrangement, the metalenses 152B, 152G, and 152R corresponding to asymmetric lenses (decentered lenses). Here, the symmetric arrangement refers to a symmetric arrangement with respect to the geometric center position of the subpixel 10 in plan view, and the asymmetric arrangement refers to an asymmetric arrangement with respect to the geometric center position of the subpixel 10 in plan view.

### 7 Modifications

Although the first to sixth embodiments of the present disclosure and modifications thereof have been specifically described above, the present disclosure is not limited to the above-described first to sixth embodiments and modifications thereof, and various modifications based on the technical idea of the present disclosure are possible.

For example, the configurations, methods, steps, shapes, materials, numerical values, and the like mentioned in the above-described first to sixth embodiments and modifications thereof are merely examples, and different configurations, methods, steps, shapes, materials, numerical values, and the like may be used as necessary.

The configurations, methods, steps, shapes, materials, numerical values, and the like of the above-described first to sixth embodiments and modifications thereof can be combined with each other without departing from the gist of the present disclosure.

The materials exemplified in the above-described first to sixth embodiments and modifications thereof can be used alone or in combination of two or more unless otherwise specified.

In the above-described first to sixth embodiments and modifications thereof, examples where the light-emitting element is an OLED element have been described, but the light-emitting element is not limited to such examples, and may be a self-luminous light-emitting element such as a light emitting diode (LED), an inorganic electro-luminescence (IEL) element, or a semiconductor laser element. The display device may be provided with two or more types of light-emitting elements.

In the above-described first to sixth embodiments and modifications thereof, examples where the light-emitting device is a display device have been described, but the light-emitting device is not necessarily a display device, and may be a lighting device or the like.

Furthermore, the present disclosure may also employ the following configurations.

(1)

A light-emitting device including:
a plurality of light-emitting elements arranged two-dimensionally;
a metamaterial; and
an optical control layer provided between the plurality of light-emitting elements and the metamaterial,
in which a ratio (L/D) of a distance L between the light-emitting elements and the metamaterial to a size D of a pixel is greater than or equal to 0.2 and less than or equal to 1.8.
   (2)

The light-emitting device according to (1),
in which the distance L between the light-emitting elements and the metamaterial is greater than or equal to 0.2×D μm and less than or equal to 1.8×D μm, and the size D of the pixel is greater than or equal to 1 μm and less than or equal to 10 μm.
   (3)

The light-emitting device according to (1) or (2), further including
a protective layer covering the plurality of light-emitting elements,
in which the optical control layer is higher in refractive index than the protective layer.
   (4)

The light-emitting device according to (1) or (2), further including
a protective layer covering the plurality of light-emitting elements,
in which a layer, either the optical control layer or the protective layer, with a greater film thickness is higher in refractive index.
   (5)

The light-emitting device according to any one of (1) to (4),
in which the metamaterial is provided substantially across an entire pixel region.
   (6)

The light-emitting device according to any one of (1) to (5),
in which the metamaterial forms a plurality of metalenses.
   (7)

The light-emitting device according to (6),
in which the plurality of light-emitting elements includes a plurality of first light-emitting elements capable of emitting first light, a plurality of second light-emitting elements capable of emitting second light, and a plurality of third light-emitting elements capable of emitting third light,
the plurality of metalenses includes a plurality of first metalenses, a plurality of second metalenses, and a plurality of third metalenses,
the first metalenses are provided above the first light-emitting elements,
the second metalenses are provided above the second light-emitting elements, and
the third metalenses are provided above the third light-emitting elements.
   (8)

The light-emitting device according to (6) or (7),
in which the metalens adjacent to each other overlap.
   (9)

The light-emitting device according to (8),
in which the metamaterial is configured such that three or more of the metalenses do not overlap.
   (10)

The light-emitting device according to (6), in which
the metamaterial includes:
an overlap region where the metalenses overlap; and
a non-overlap region where the metalenses do not overlap, and
the overlap region and the non-overlap region each include a two-dimensional metamaterial.
   (11)

The light-emitting device according to (6),
in which the metamaterial includes:
an overlap region where the metalenses overlap; and
a non-overlap region where the metalenses do not overlap, and
the overlap region and the non-overlap region each include a three-dimensional metamaterial.
   (12)

The light-emitting device according to claim (6),
in which the metamaterial includes:
an overlap region where the metalenses overlap; and
a non-overlap region where the metalenses do not overlap,
the overlap region include a three-dimensional metamaterial, and
the non-overlap region include a two-dimensional metamaterial.
   (13)

The light-emitting device according to any one of (1) to (12),
in which the metamaterial includes a plurality of nanostructures arranged two-dimensionally.
   (14)

The light-emitting device according to (13),
in which the nanostructures provided in a central portion of the pixel is different in height from the nanostructures provided in a boundary between the pixels.
   (15)

The light-emitting device according to (13) or (14),
in which the metamaterial includes a uniform arrangement region where a distance between the nanostructures is constant and a non-uniform arrangement region where the distance between the nanostructures varies and
the non-uniform arrangement region is provided in a boundary region between the pixels.
   (16)

The light-emitting device according to any one of (1) to (4), further including
a plurality of lenses,
in which the metamaterial is provided around each of the lenses.
   (17)

The light-emitting device according to any one of (1) to (4), further including
a grating,
in which the metamaterial forms a plurality of metalenses, and
the grating is provided around each of the metalenses.
   (18)

The light-emitting device according to any one of (1) to (4), further including
a phase shifter,
in which the metamaterial is provided above or below the phase shifter.
   (19)

The light-emitting device according to any one of (1) to (18), further including
a color filter provided between the plurality of light-emitting elements and the metamaterial.
   (20)

Electronic equipment including the light-emitting device according to any one of (1) to (19).

### 8 Example of Resonator Structure Applied to Each Embodiment

The pixel used in the above-described display device according to the present disclosure may have a configuration including a resonator structure that resonates light generated by the light-emitting element. Hereinafter, the resonator structure will be described with reference to the drawings. Furthermore, in the following description, the first surface of each layer may be referred to as upper surface.

### Resonator Structure: First Example

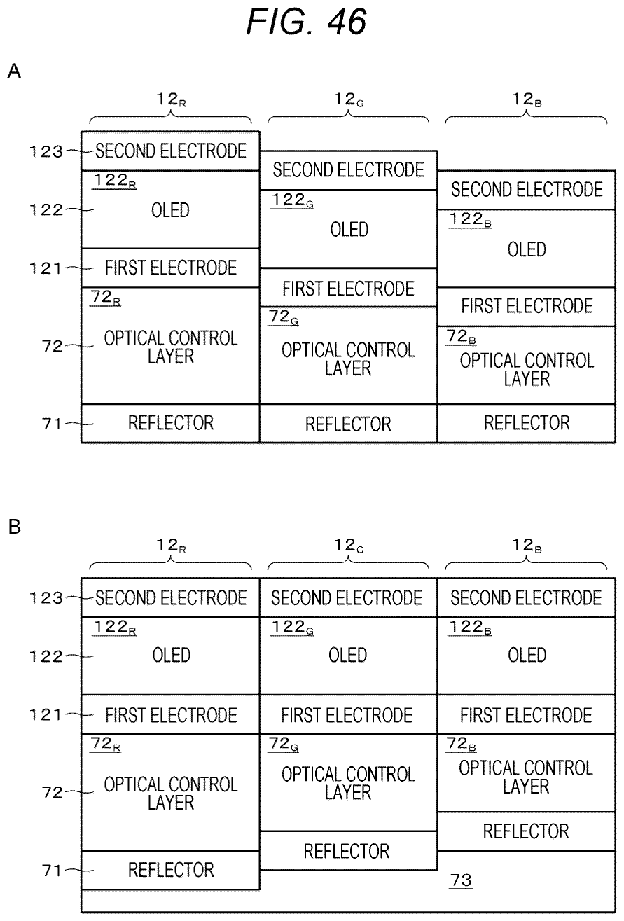

FIG. 46A is a schematic cross-sectional view for describing a first example of a resonator structure. In the following description, the light-emitting elements 12 provided corresponding to the subpixels 10R, 10G, and 10B may be referred to as light-emitting elements 12_{R}, 12_{G}, and 12_{B}, respectively. Furthermore, portions of the OLED layer 122 corresponding to the subpixels 10R, 10G, and 10B may be referred to OLED layer 122_{R}, OLED layer 122_{G}, and OLED layer 122_{B}, respectively.

In the first example, the first electrode layer 121 is formed with a uniform film thickness across the light-emitting elements 12. This similarly applies to the second electrode 123.

A reflector 71 is arranged below the first electrode 121 of the light-emitting element 12 with an optical control layer 72 interposed therebetween. A resonator structure that causes resonance of light generated by the OLED layer 122 is formed between the reflector 71 and the second electrode 123. In the following description, the optical control layers 72 provided corresponding to the subpixels 10R, 10G, and 10B are referred to as optical control layers 72_{R}, 72_{G}, and 72_{B}, respectively.

The reflector 71 is formed with a uniform film thickness across the light-emitting elements 12. The film thickness of the optical control layer 72 varies in a manner that depends on a color to be displayed by the pixel. Since the optical control layers 72_{R}, 72_{G}, and 72_{B} have different film thicknesses, it is possible to set an optical distance at which optimum resonance occurs for a wavelength of light corresponding to the color to be displayed.

In the example illustrated in FIG. 46A, the upper surfaces of the reflectors 71 in the light-emitting elements 12_{R}, 12_{G}, and 12_{B} are flush with each other. As described above, since the film thickness of the optical control layer 72 varies in a manner that depends on the color to be displayed by the pixel, the position of the upper surface of the second electrode layer 123 varies in a manner that depends on the types of the light-emitting elements 12_{R}, 12_{G}, and 12_{B}.

The reflector 71 can include a metal such as aluminum (Al), silver (Ag), or copper (Cu), or an alloy containing these as principal components, for example.

The optical control layer 72 can include an inorganic insulating material such as a silicon nitride (SiNₓ), a silicon oxide (SiOₓ), or a silicon oxynitride (SiOₓN_{y}), or an organic resin material such as an acrylic resin or a polyimide resin. The optical control layer 72 may be a single layer, or may be a multilayer film including such a plurality of materials. Furthermore, the number of layers may vary in a manner that depends on the type of the light-emitting element 12.

The first electrode 121 can include a transparent conductive material such as an indium tin oxide (ITO), an indium zinc oxide (IZO), or a zinc oxide (ZnO).

The second electrode 123 needs to function as a semi-transparent reflective film. The second electrode 123 can include magnesium (Mg), silver (Ag), a magnesium-silver alloy (MgAg) containing these materials as principal components, an alloy containing an alkali metal or an alkaline earth metal, or the like.

### Resonator Structure: Second Example

FIG. 46B is a schematic cross-sectional view for describing a second example of the resonator structure.

In the second example as well, the first electrode 121 and the second electrode 123 are each formed with a uniform film thickness across the light-emitting elements 12.

In addition, in the second example as well, the reflector 71 is arranged below the first electrode 121 of the light-emitting element 12 with the optical control layer 72 interposed therebetween. A resonator structure that causes resonance of light generated by the OLED layer 122 is formed between the reflector 71 and the second electrode 123. Similarly to the first example, the reflector 71 is formed with a uniform film thickness across the light-emitting elements 12, and the film thickness of the optical control layer 72 varies in a manner that depends on the color to be displayed by the pixel.

In the first example illustrated in FIG. 46A, the reflectors 71 are arranged to make their respective upper surfaces flush with each other across the light-emitting elements 12_{R}, 12_{G}, and 12_{B}, and the positions of the upper surfaces of the second electrodes 123 vary in a manner that depends on the types of the light-emitting elements 12_{R}, 12_{G}, and 12_{B}.

On the other hand, in the second example illustrated in FIG. 46B, the upper surfaces of the second electrodes 123 are flush with each other across the light-emitting elements 12_{R}, 12_{G}, and 12_{B}. In order to make the upper surfaces of the second electrodes 123 flush with each other, in the light-emitting elements 12_{R}, 12_{G}, and 12_{B}, the reflectors 71 are arranged such that the positions of their respective upper surfaces vary in a manner that depends on the types of the light-emitting elements 12_{R}, 12_{G}, and 12_{B}. Therefore, the lower surfaces of the reflectors 71 (in other words, the upper surface of an underlayer (insulating layer) 73) form a stair shape according to the types of the light-emitting elements 12.

Materials and the like constituting the reflector 71, the optical control layer 72, the first electrode 121, and the second electrode 123 are similar to those described in the first example, and thus, the description thereof will be omitted.

### Resonator Structure: Third Example

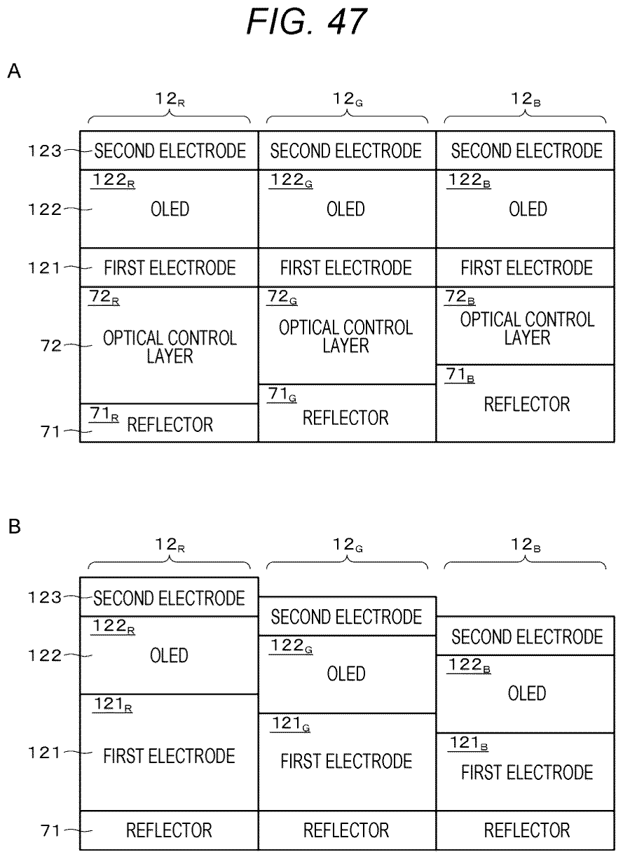

FIG. 47A is a schematic cross-sectional view for describing a third example of the resonator structure. In the following description, the reflectors 71 provided corresponding to the subpixels 10R, 10G, and 10B may be referred to as reflectors 71_{R}, 71_{G}, and 71_{B}, respectively.

In the third example as well, the first electrode 121 and the second electrode 123 are each formed with a uniform film thickness across the light-emitting elements 12.

In addition, in the third example as well, the reflector 71 is arranged below the first electrode 121 of the light-emitting element 12 with the optical control layer 72 interposed therebetween. A resonator structure that causes resonance of light generated by the OLED layer 122 is formed between the reflector 71 and the second electrode 123. Similarly to the first and the second examples, the film thickness of the optical control layer 72 varies in a manner that depends on the color to be displayed by the pixel. In addition, similarly to the second example, the second electrodes 123 are arranged to make their respective upper surfaces flush with each other across the light-emitting elements 12_{R}, 12_{G}, and 12_{B}.

In the second example illustrated in FIG. 46B, to make the upper surfaces of the second electrodes 123 flush with each other, the lower surfaces of the reflectors 71 form a stair shape according to the types of the light-emitting elements 12.

On the other hand, in the third example illustrated in FIG. 47A, the film thickness of the reflector 71 is set to vary in a manner that depends on the types of the light-emitting elements 12_{R}, 12_{G}, and 12_{B}. More specifically, the film thickness is set to make the lower surfaces of the reflectors 71_{R}, 71_{G}, and 71_{B} flush with each other.

Materials and the like constituting the reflector 71, the optical control layer 72, the first electrode 121, and the second electrode 123 are similar to those described in the first example, and thus, the description thereof will be omitted.

### Resonator Structure: Fourth Example

FIG. 47B is a schematic cross-sectional view for describing a fourth example of the resonator structure. In the following description, the first electrodes 121 provided corresponding to the subpixels 10R, 10G, and 10B will be referred to as first electrodes 121_{R}, 121_{G}, and 121_{B}, respectively.

In the first example illustrated in FIG. 46A, the first electrode 121 and the second electrode 123 of each light-emitting element 12 are formed with a uniform film thickness. In addition, the reflector 71 is arranged below the first electrode 121 of the light-emitting element 12 with the optical control layer 72 interposed therebetween.

On the other hand, in the fourth example illustrated in FIG. 47B, the optical control layer 72 is omitted, and the film thickness of the first electrode 121 is set to vary in a manner that depends on the types of the light-emitting elements 12_{R}, 12_{G}, and 12_{B}.

The reflector 71 is formed with a uniform film thickness across the light-emitting elements 12. The film thickness of the first electrode 121 varies in a manner that depends on the color to be displayed by the pixel. Since the first electrodes 121_{R}, 121_{G}, and 121_{B} have different film thicknesses, it is possible to set an optical distance that causes optimum resonance for a wavelength of light according to the color to be displayed.

Materials and the like constituting the reflector 71, the optical control layer 72, the first electrode 121, and the second electrode 123 are similar to those described in the first example, and thus, the description thereof will be omitted.

### Resonator Structure: Fifth Example

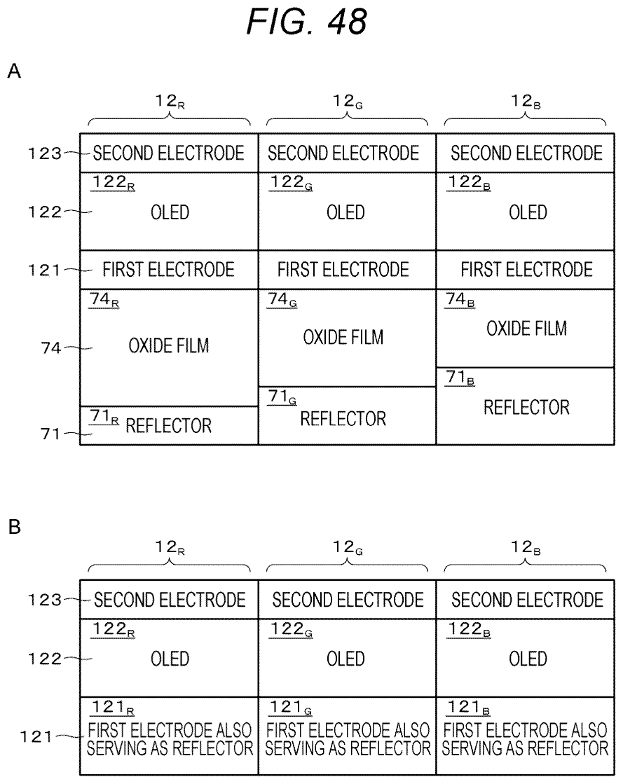

FIG. 48A is a schematic cross-sectional view for describing a fifth example of the resonator structure.

In the first example illustrated in FIG. 46A, the first electrode 121 and the second electrode 123 are each formed with a uniform film thickness across the light-emitting elements 12. In addition, the reflector 71 is arranged below the first electrode 121 of the light-emitting element 12 with the optical control layer 72 interposed therebetween.

On the other hand, in the fifth example illustrated in FIG. 48A, the optical control layer 72 is omitted, and instead, an oxide film 74 is formed on the reflector 71. The film thickness of the oxide film 74 is set to vary in a manner that depends on the types of the light-emitting elements 12_{R}, 12_{G}, and 12_{B}. In the following description, the oxide films 74 provided corresponding to the subpixels 10R, 10G, and 10B are referred to as oxide films 74_{R}, 74_{G}, and 74_{B}, respectively.

The film thickness of the oxide film 74 varies in a manner that depends on the color to be displayed by the pixel. Since the oxide films 74_{R}, 74_{G}, and 74_{B} have different film thicknesses, it is possible to set an optical distance that causes optimum resonance for a wavelength of light according to the color to be displayed.

The oxide film 74 is a film obtained by oxidizing the surface of the reflector 71, and includes, for example, an aluminum oxide, a tantalum oxide, a titanium oxide, a magnesium oxide, a zirconium oxide, or the like. The oxide film 74 functions as an insulating film for adjusting the optical path length (optical distance) between the reflector 71 and the second electrode 123.

The oxide films 74 having their respective film thicknesses varying in a manner that depends on the types of the light-emitting elements 12_{R}, 12_{G}, and 12_{B} can be formed, for example, as follows.

First, an electrolytic solution is filled in a container, and a substrate on which the reflector 71 is formed is immersed in the electrolytic solution. Furthermore, an electrode is arranged to face the reflector 71.

In addition, a positive voltage is applied to the reflector 71 with reference to the electrode to anodize the reflector 71. A film thickness of the oxide film obtained as a result of the anodization is proportional to a voltage value for the electrode. Therefore, the anodization is performed with a voltage corresponding to the types of the light-emitting elements 12 applied to each of the reflectors 71_{R}, 71_{G}, and 71_{B}. As a result, the oxide films 74 having different film thicknesses can be collectively formed.

Materials and the like constituting the reflector 71, the first electrode 121, and the second electrode 123 are similar to those described in the first example, and thus, the description thereof will be omitted.

### Resonator Structure: Sixth Example

FIG. 48B is a schematic cross-sectional view for describing a sixth example of the resonator structure.

In the sixth example, the light-emitting element 12 includes a stack of the first electrode 121, the OLED layer 122, and the second electrode 123. Note that, in the sixth example, the first electrode 121 is formed to function as both an electrode and a reflector. The first electrode (also serving as reflector) 12 includes a material having an optical constant selected according to the types of the light-emitting elements 12_{R}, 12_{G}, and 12_{B}. Since a phase shift caused by the first electrode (also serving as reflector) 121 varies, it is possible to set an optical distance that causes optimum resonance for a wavelength of light according to the color to be displayed.

The first electrode (also serving as reflector) 121 can include pure metal such as aluminum (Al), silver (Ag), gold (Au), or copper (Cu), or an alloy containing these as principal components. For example, the first electrode (also serving as reflector) 121_{R} of the light-emitting element 12_{R} can include copper (Cu), and the first electrode (also serving as reflector) 121_{G} of the light-emitting element 12_{G} and the first electrode (also serving as reflector) 121_{B} of the light-emitting element 12_{B} can include aluminum.

Materials and the like constituting the second electrode 123 are similar to those described in the first example, and thus, the description thereof will be omitted.

### Resonator Structure: Seventh Example

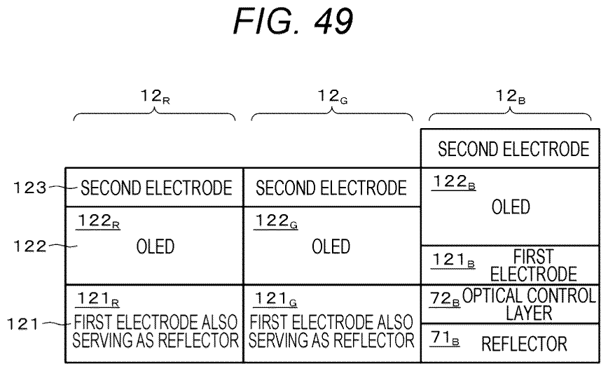

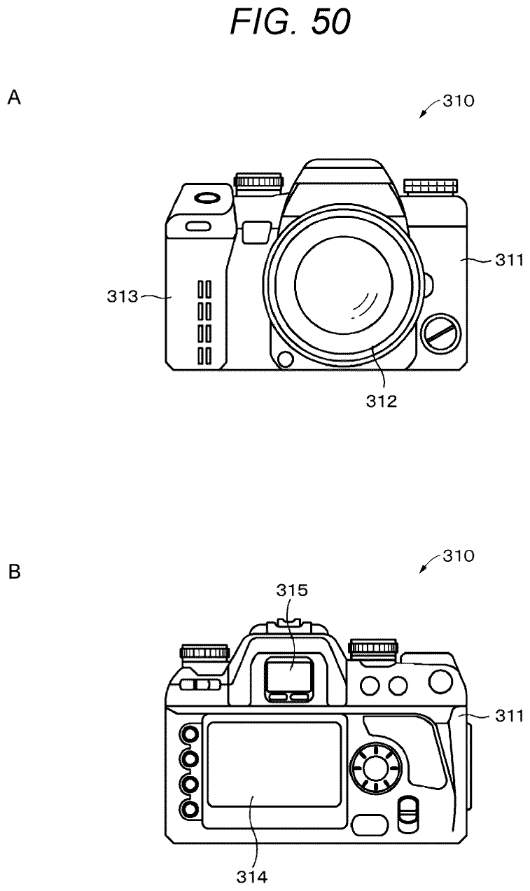

FIG. 49 is a schematic cross-sectional view for describing a seventh example of the resonator structure.

The seventh example basically has a configuration where the sixth example is applied to the light-emitting elements 12_{R} and 12_{G}, and the first example is applied to the light-emitting elements 12_{B}. With this configuration as well, it is possible to set an optical distance that causes optimum resonance for a wavelength of light according to the color to be displayed.

The first electrodes (also serving as reflectors) 121_{R} and 121_{G} used for the light-emitting elements 12_{R} and 12_{G} can include pure metal such as aluminum (Al), silver (Ag), gold (Au), or copper (Cu), or an alloy containing these as principal components.

Materials and the like constituting the reflector 71_{B}, the optical control layer 72_{B}, and the first electrode 121_{B} used for the light-emitting element 12B are similar to those described in the first example, and thus, the description thereof will be omitted.

### 9 Application Examples

### Electronic Equipment

The display devices 101, 102, 103, 104, 105, and 106 (hereinafter, referred to as “the display device 101 and the like”) according to the first to sixth embodiments and the modifications thereof described above can be included in various types of electronic equipment. The display device 101 and the like are suitable especially for an electronic viewfinder of a video camera or a single-lens reflex camera, a head-mounted display, or the like that requires high resolution and is used near the eyes in an enlarged manner.

### Specific Example 1

FIGS. 50A and 50B illustrate an example of an external appearance of a digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip portion 313 to be held by the photographer on the front left side.

A monitor 314 is provided at a position shifted to the left side from the center of the back surface of the camera main body 311. An electronic viewfinder (eyepiece window) 315 is provided above the monitor 314. By looking through the electronic viewfinder 315, the photographer can visually recognize an optical image of a subject guided from the imaging lens unit 312, and determine a picture composition. The electronic viewfinder 315 includes any of the above-described display device 101 and the like.

### Specific Example 2

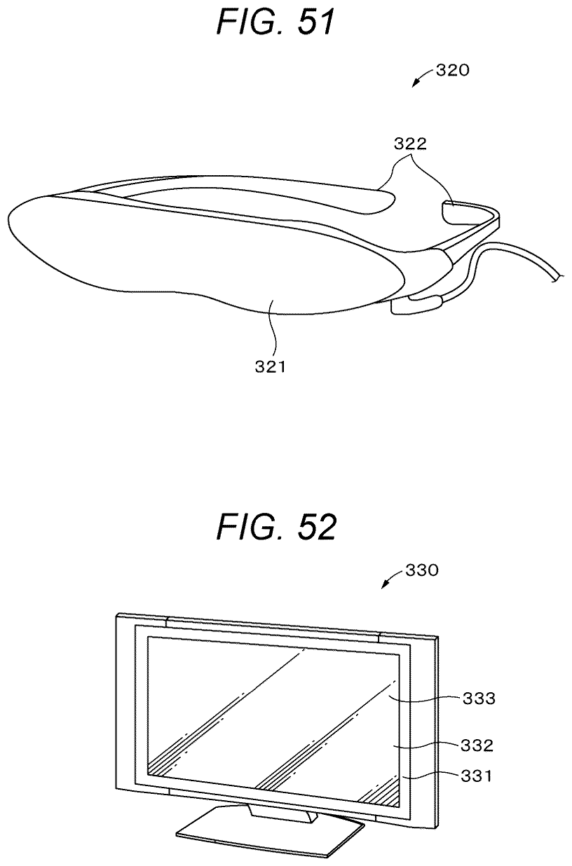

FIG. 51 illustrates an example of an external appearance of a head-mounted display 320. The head-mounted display 320 includes, for example, ear hooking portions 322 for a user to wear the head-mounted display 320 on the head, on both sides of a display unit 321 having a shape of eyeglasses. The display unit 321 includes any one of the above-described display device 101 and the like.

### Specific Example 3

FIG. 52 illustrates an example of an external appearance of a television device 330. The television device 330 includes, for example, a video display screen unit 331 including a front panel 332 and a filter glass 333, and the video display screen unit 331 includes any one of the above-described display device 101 and the like.

### Specific Example 4

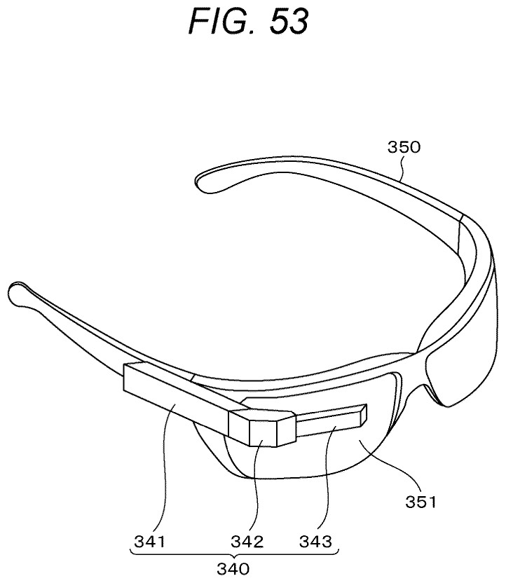

FIG. 53 Illustrates an Example of an External appearance of a see-through head-mounted display 340. The see-through head-mounted display 340 includes a main body 341, an arm 342, and a lens barrel 343.

The main body 341 is connected to the arm 342 and eyeglasses 350. Specifically, the main body 341 has an end portion in the long side direction coupled to the arm 342, and the main body 341 has one side of a side surface coupled to the eyeglasses 350 via a connecting member. Note that the main body 341 may be mounted directly on the head of the human body.

The main body 341 includes a control board for controlling operations of the see-through head-mounted display 340, and a display unit. The arm 342 connects the main body 341 and the lens barrel 343, and supports the lens barrel 343. Specifically, the arm 342 is coupled to an end portion of the main body 341 and an end portion of the lens barrel 343 to secure the lens barrel 343. Furthermore, the arm 342 incorporates a signal line for communicating data related to an image to be provided from the main body 341 to the lens barrel 343.

The lens barrel 343 projects image light provided from the main body 341 through the arm 342 toward the eyes of the user wearing the see-through head-mounted display 340 through an eyeglass 351. In this see-through head-mounted display 340, the display unit of the main body 341 includes one of the above-described display device 101 and the like.

### Specific Example 5

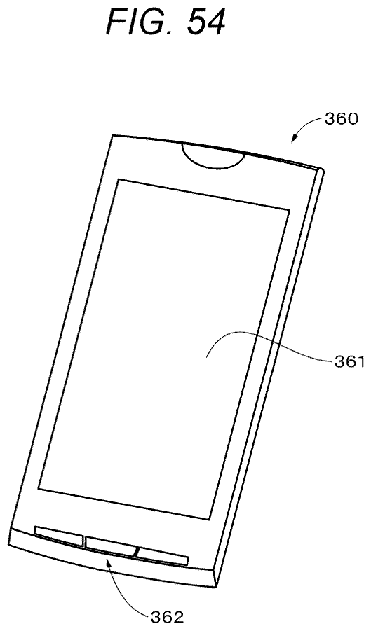

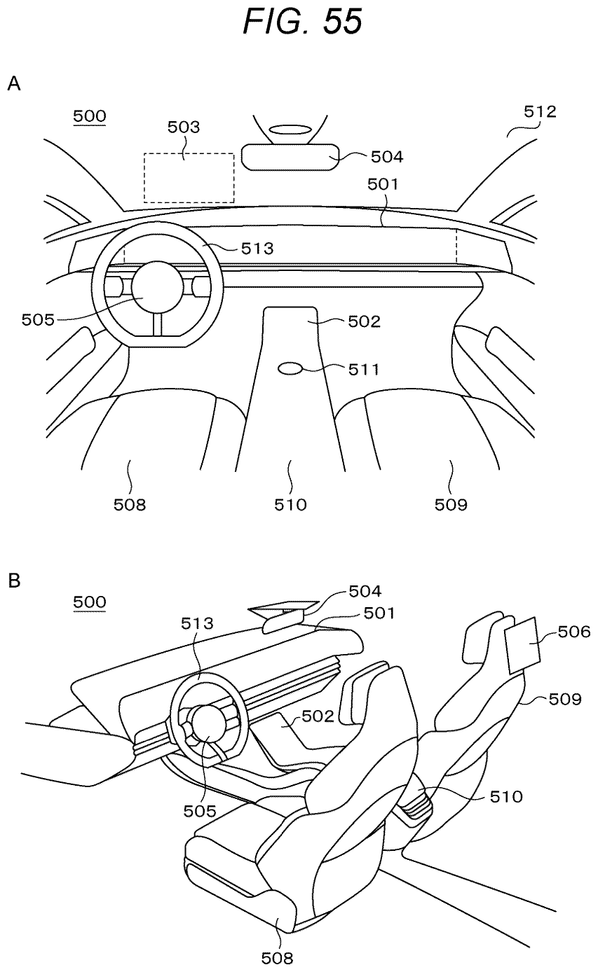

FIG. 54 illustrates an example of an external appearance of a smartphone 360. The smartphone 360 includes a display unit 361 that displays various kinds of information, an operation unit 362 including a button for receiving operation input from the user, and the like. The display unit 361 includes any one of the above-described display device 101 and the like.

### Specific Example 6

The above-described display device 101 and the like may be provided in various displays provided in vehicles.

FIGS. 55A and 55B are diagrams illustrating an example of an internal configuration of a vehicle 500 provided with various displays. Specifically, FIG. 55A is a diagram illustrating an example of an internal state of the vehicle 500 as viewed from the rear to the front of the vehicle 500, and FIG. 55B is a view illustrating an example of an internal state of the vehicle 500 as viewed from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes any one of the above-described display device 101 and the like. For example, all of these displays may include one of the above-described display device 101 and the like.

The center display 501 is arranged on the dashboard at a location facing a driver's seat 508 and a passenger seat 509. FIGS. 55A and 55B illustrate an example of the center display 501 having a horizontally elongated shape extending from the driver's seat 508 side to the passenger seat 509 side, but the screen size and the location of the center display 501 are determined as appropriate. The center display 501 can display information sensed by various sensors. As a specific example, the center display 501 can display an image captured by an image sensor, a distance image to an obstacle present in front of or on a side of the vehicle 500, the distance being measured by a ToF sensor, a passenger's body temperature detected by an infrared sensor, the like. The center display 501 can be used to display at least one piece of information including safety-related information, operation-related information, lifelogs, health-related information, authentication/identification-related information, and entertainment-related information, for example.

The safety-related information is information such as doze sensing, looking-away sensing, sensing of mischief of a child riding together, and presence or absence of wearing of a seat belt, sensing of leaving of an occupant, and is information sensed by a sensor arranged, for example, to overlap with the back surface side of the center display 501. The operation-related information is information obtained by using the sensor to sense a gesture related to an operation performed by the occupant. Gestures to be sensed may include operations of various types of equipment in the vehicle 500. For example, operations of air conditioning equipment, a navigation device, an audiovisual (AV) device, a lighting device, and the like are detected. The life log include lifelogs of all the occupants. For example, the lifelogs include an action record of each occupant in the vehicle. By acquiring and storing the lifelogs, it is possible to check the state of each occupant at the time of an accident. The health-related information is information obtained by sensing the body temperature of the occupant using a sensor such as a temperature sensor, and estimating the health condition of the occupant on the basis of the sensed body temperature. Alternatively, the face of the occupant may be imaged by using an image sensor, and the health condition of the occupant may be estimated from the imaged facial expression. Moreover, a conversation may be made with the occupant in automatic voice, and the health condition of the occupant may be estimated on the basis of the contents of a response from the occupant. The authentication/identification-related information includes information on a keyless entry function of performing face authentication by using a sensor, and a function of automatically adjusting a seat height and position through face identification. The entertainment-related information includes information on a function of detecting, with a sensor, operation information about an AV device being used by the occupant, and a function of recognizing the face of the occupant with the sensor and providing content suitable for the occupant through the AV device.

The console display 502 can be used to display lifelog information, for example. The console display 502 is arranged near a shift lever 511 of a center console 510 between the driver's seat 508 and the passenger seat 509. The console display 502 can also display information sensed by various sensors. Furthermore, the console display 502 may display an image of the surroundings of the vehicle captured with an image sensor, or may display a distance image to an obstacle present in the surroundings of the vehicle.

The head-up display 503 is virtually displayed behind a windshield 512 in front of the driver's seat 508. The head-up display 503 can be used to display at least one piece of information including the safety-related information, the operation-related information, the lifelogs, the health-related information, the authentication/identification-related information, and the entertainment-related information, for example. Being virtually arranged in front of the driver's seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but also display the state of an occupant in the rear seat, and thus, can be used to display the lifelog information by disposing a sensor on the back surface side of the digital rearview mirror 504 in an overlapping manner, for example.

The steering wheel display 505 is arranged near the center of a steering wheel 513 of the vehicle 500. The steering wheel display 505 can be used to display at least one piece of information including the safety-related information, the operation-related information, the lifelogs, the health-related information, the authentication/identification-related information, and the entertainment-related information, for example. In particular, being located close to the driver's hands, the steering wheel display 505 is suitable for displaying the lifelog information such as the body temperature of the driver, or for displaying information regarding operations of the AV device, the air conditioning equipment, or the like.

The rear entertainment display 506 is attached to the back surface side of the driver's seat 508 or the passenger seat 509, and is for the occupant in the rear seat to enjoy viewing/listening. The rear entertainment display 506 can be used to display at least one piece of information including the safety-related information, the operation-related information, the lifelogs, the health-related information, the authentication/identification-related information, and the entertainment-related information, for example. In particular, as the rear entertainment display 506 is located in front of the occupant in the rear seat, information related to the occupant in the rear seat is displayed. For example, information regarding the operation of the AV device or the air conditioning equipment may be displayed, or a result of measurement of the body temperature or the like of the occupant in the rear seat with a temperature sensor may be displayed on the display.

A sensor may be arranged on the back surface side of the display device 101 and the like in an overlapping manner, so that the distance to an object present in the surroundings can be measured. Optical distance measurement methods are roughly classified into a passive type and an active type. By the method of the passive type, distance measurement is performed by receiving light from an object, without projecting light from a sensor onto the object. Examples of the method of the passive type include a lens focus method, a stereo method, and a monocular vision method. By the method of the active type, distance measurement is performed by projecting light onto an object, and receiving reflected light from the object with a sensor to measure the distance. Examples of the method of the active type include an optical radar system, an active stereo system, a photometric stereo method, a moire topography method, an interferometry method, and the like. Any of the above-described display device 101 and the like can be used in distance measurement by any of these methods. With a sensor arranged on the back surface side of the above-described display device 101 and the like in an overlapping manner, distance measurement of the passive type or the active type described above can be performed.

### REFERENCE SIGNS LIST

10R, 10G, 10B Subpixel
11 Drive substrate
12R, 12G, 12B Light-emitting element
13 Protective layer
14 Optical control layer
15 Metamaterial
15RE Nanostructure formation region
15RE1 Non-overlap region
15RE2, 15RE3 Overlap region
16 Protective layer
17 Cover layer
18 Planarization layer
19F Color filter
19FR Red filter portion
19FG Green filter portion
19FB Blue filter portion
21, 22 Compound layer
51 Resist layer
52 Resist pattern
101, 102, 103, 104, 105, 106 Display device
101A Pad portion
121 First electrode
122R, 122G, 122B OLED layer
123 Second electrode
151 Nanostructure
152R, 152G, 152B Metalens
154 High dielectric material layer
155 Light source
156 Three-dimensional metamaterial
210R, 210G, 210B Compound lens
211R, 211G, 211B Lens
212R, 212G, 212B Metasurface
213R, 213G, 213B Lens
214R, 213G, 213B Metasurface
215R, 215G, 215B Grating
216 Structure
220R, 220G, 220B Compound lens
221R, 221G, 221B Phase shifter
222R, 222G, 222B Metalens
310 Digital still camera
320 Head-mounted display
330 Television device
340 See-through head-mounted display
360 Smartphone
500 Vehicle
RE1 Display region
RE2 Peripheral region
10RE1 Uniform arrangement region
10RE2 Non-uniform arrangement region

1. A light-emitting device comprising:
a plurality of light-emitting elements arranged two-dimensionally;
a metamaterial; and
an optical control layer provided between the plurality of light-emitting elements and the metamaterial,
wherein a ratio (L/D) of a distance L between the light-emitting elements and the metamaterial to a size D of a pixel is greater than or equal to 0.2 and less than or equal to 1.8.

2. The light-emitting device according to claim 1,
wherein the distance L between the light-emitting elements and the metamaterial is greater than or equal to 0.2×D μm and less than or equal to 1.8×D μm, and
the size D of the pixel is greater than or equal to 1 μm and less than or equal to 10 μm.

3. The light-emitting device according to claim 1, further comprising
a protective layer covering the plurality of light-emitting elements,
wherein the optical control layer is higher in refractive index than the protective layer.

4. The light-emitting device according to claim 1, further comprising a protective layer covering the plurality of light-emitting elements,
wherein a layer, either the optical control layer or the protective layer, with a greater film thickness is higher in refractive index.

5. The light-emitting device according to claim 1,
wherein the metamaterial is provided substantially across an entire pixel region.

6. The light-emitting device according to claim 1,
wherein the metamaterial forms a plurality of metalenses.

7. The light-emitting device according to claim 6,
wherein the plurality of light-emitting elements includes a plurality of first light-emitting elements capable of emitting first light, a plurality of second light-emitting elements capable of emitting second light, and a plurality of third light-emitting elements capable of emitting third light,
the plurality of metalenses includes a plurality of first metalenses, a plurality of second metalenses, and a plurality of third metalenses,
the first metalenses are provided above the first light-emitting elements,
the second metalenses are provided above the second light-emitting elements, and
the third metalenses are provided above the third light-emitting elements.

8. The light-emitting device according to claim 6,
wherein the metalenses adjacent to each other overlap.

9. The light-emitting device according to claim 8,
wherein the metamaterial is configured such that three or more of the metalenses do not overlap.

10. The light-emitting device according to claim 6,
wherein the metamaterial includes:
an overlap region where the metalenses overlap; and
a non-overlap region where the metalenses do not overlap, and
the overlap region and the non-overlap region each include a two-dimensional metamaterial.

11. The light-emitting device according to claim 6,
wherein the metamaterial includes:
an overlap region where the metalenses overlap; and
a non-overlap region where the metalenses do not overlap, and
the overlap region and the non-overlap region each include a three-dimensional metamaterial.

12. The light-emitting device according to claim 6,
wherein the metamaterial includes
an overlap region where the metalenses overlap, and
a non-overlap region where the metalenses do not overlap,
the overlap region include a three-dimensional metamaterial, and
the non-overlap region include a two-dimensional metamaterial.

13. The light-emitting device according to claim 1,
wherein the metamaterial includes a plurality of nanostructures arranged two-dimensionally.

14. The light-emitting device according to claim 13,
wherein the nanostructures provided in a central portion of the pixel is different in height from the nanostructures provided in a boundary between the pixels.

15. The light-emitting device according to claim 13,
wherein the metamaterial includes a uniform arrangement region where a distance between the nanostructures is constant and a non-uniform arrangement region where the distance between the nanostructures varies and
the non-uniform arrangement region is provided in a boundary region between the pixels.

16. The light-emitting device according to claim 1, further comprising a plurality of lenses,
wherein the metamaterial is provided around each of the lenses.

17. The light-emitting device according to claim 1, further comprising a grating,
wherein the metamaterial forms a plurality of metalenses, and
the grating is provided around each of the metalenses.

18. The light-emitting device according to claim 1, further comprising a phase shifter,
wherein the metamaterial is provided above or below the phase shifter.

19. The light-emitting device according to claim 1, further comprising a color filter provided between the plurality of light-emitting elements and the metamaterial.

20. Electronic equipment comprising the light-emitting device according to claim 1.
